(19) United States
(12) Patent Application Publication
(10) Pub. No.: US 2026/0076183 A1
(43) Pub. Date: Mar. 12, 2026

(54) ELECTRONIC DEVICE

(71) Applicant: FUJI ELECTRIC CO., LTD., Kawasaki-shi (JP)

(72) Inventors: Yoshihiro TATEISHI, Matsumoto-city (JP); Yuta TAMAI, Matsumoto-city (JP); Tsubasa WATAKABE, Matsumoto-city (JP); Daisuke INOUE, Matsumoto-city (JP); Kengo INOUE, Matsumoto-city (JP)

(73) Assignee: FUJI ELECTRIC CO., LTD., Kawasaki-shi (JP)

(21) Appl. No.: 19/318,743

(22) Filed: Sep. 4, 2025

(30) Foreign Application Priority Data
Sep. 10, 2024 (JP) 2024-156919

(51) Int. Cl. H01L 23/367; H01L 23/373

(52) U.S. Cl. CPC H10W 40/22; H10W 40/258

(57) ABSTRACT

The electronic device includes a semiconductor module provided on a heat sink including a first joined surface portion. The semiconductor module includes a heat dissipation plate including a second joined surface portion joined to the first joined surface portion via a thermally-conductive bonding material, and a transistor chip placed on a side of the heat dissipation plate which is opposite to the second joined surface portion. At least one joined surface portion out of the first joined surface portion and the second joined surface portion includes a plurality of protrusions protruding toward the other joined surface portion out of the first joined surface portion and the second joined surface portion, a first recess placed between the protrusions and recessed in a direction away from the other joined surface portion, and a second recess placed outward of the plurality of protrusions and recessed in a direction away from the other joined surface portion. A thickness at the first recess of the thermally-conductive bonding material is greater than a thickness at the protrusions thereof, and a thickness at the second recess of the thermally-conductive bonding material is greater than the thickness at the first recess.

### CROSS REFERENCE TO RELATED APPLICATIONS AND INCORPORATION BY REFERENCE

This application claims benefit of priority under 35 U.S.C. § 119 based on Japanese Patent Application No. 2024-156919 filed on Sep. 10, 2024, the entire contents of which are incorporated by reference herein.

### TECHNICAL FIELD

This technology (a technology according to this disclosure) relates to an electronic device, particularly, to a technology that is effective when the technology is applied to an electronic device including a semiconductor module provided on a heat sink.

### BACKGROUND ART

As an electronic device, Patent Documents 1 to 5 as listed below disclose electronic devices in each of which a heat dissipation plate (a metal plate) of a semiconductor module is joined to a heat sink (a radiator) of a baseplate, a heat spreader, a heat dissipation member, a packaging base material, or the like via a thermally-conductive bonding material. Patent Documents 1 to 5 also disclose technologies in each of which the heat dissipation plate or the heat sink has recesses (grooves).
Patent Document 1: JP 2002-280503 A
Patent Document 2: JP 2016-001766 A
Patent Document 3: JP 2007-149725 A
Patent Document 4: JPWO 2015/102046 A1
Patent Document 5: JP 2013-008771 A

### SUMMARY OF INVENTION

### Technical Problem

In the above-mentioned electronic devices, stress is caused in the thermally-conductive bonding material between the heat sink and the heat dissipation plate of the semiconductor module. Accordingly, the thermally-conductive bonding material is required to have a heat dissipation function (a heat transfer function) to dissipate (transfer) heat generated in the semiconductor module to the heat sink, and a joining function (peeling resistance and breakage resistance) to join the heat dissipation plate of the semiconductor module to the heat sink.

In view of this, the film thickness of the thermally-conductive bonding material is thickened to relax the stress caused in the thermally-conductive bonding material, thereby making it possible to enhance the joining function of the thermally-conductive bonding material. However, if the film thickness of the thermally-conductive bonding material is thickened, the heat dissipation function of the thermally-conductive bonding material decreases.

That is, in conventional electronic devices, the heat dissipation function and the joining function of the thermally-conductive bonding material are in a trade-off relationship, and it is difficult to improve both functions. The heat dissipation function and the joining function of the thermally-conductive bonding material influence the reliability of the electronic device, and there is room for improvement.

An object of the technology of this disclosure is to improve the reliability and the heat dissipation property of an electronic device.

### Solution to Problem

An electronic device according to one aspect of the technology of this disclosure includes a heat sink, and a semiconductor module provided on the heat sink.

The heat sink includes a first joined surface portion.

The semiconductor module includes a heat dissipation plate including a second joined surface portion joined to the first joined surface portion via a thermally-conductive bonding material, and a transistor chip placed on a side of the heat dissipation plate provided on an opposite side to the second joined surface portion.

At least one joined surface portion out of the first joined surface portion and the second joined surface portion includes a plurality of protrusions protruding toward the other joined surface portion out of the first joined surface portion and the second joined surface portion, a first recess placed between the protrusions and recessed in a direction away from the other joined surface portion, and a second recess placed outward of the plurality of protrusions and recessed in the direction away from the other joined surface portion.

A thickness at the first recess of the thermally-conductive bonding material is greater than a thickness at the protrusions, and a thickness at the second recess of the thermally-conductive bonding material is greater than the thickness at the first recess.

### Advantageous Effects of Invention

The one aspect of the technology of this disclosure can improve the reliability and the heat dissipation property of an electronic device.

### BRIEF DESCRIPTION OF DRAWINGS

FIG. 1 is an equivalent circuit diagram of an electronic device according to a first embodiment of the technology of this disclosure.

FIG. 2 is a main plan view schematically illustrating an arrangement state of semiconductor modules provided on a heat sink in the electronic device according to the first embodiment of the technology of this disclosure.

FIG. 3 is a plan view schematically illustrating an internal structure of the semiconductor module illustrated in FIG. 2 by removing part of a resin sealing body.

FIG. 4A is a longitudinal sectional view schematically illustrating a longitudinal sectional structure along a cutting plane line a3-a3 in FIG. 3.

FIG. 4B is a main longitudinal sectional view illustrating part of FIG. 4A in an enlarged manner.

FIG. 5 is a longitudinal sectional view schematically illustrating a longitudinal sectional structure along a cutting plane line b3-b3 in FIG. 3.

FIG. 6 is a longitudinal sectional view schematically illustrating a longitudinal sectional structure along a cutting plane line c3-c3 in FIG. 3.

FIG. 7 is a bottom plan view schematically illustrating a bottom side of the semiconductor module illustrated in FIG. 4A.

FIG. 8 is a plan view schematically illustrating a pattern of recesses and protrusions provided on the heat sink illustrated in FIG. 3.

FIG. 9 is a view illustrating Reference Example 1-1 according to the first embodiment of the technology of this disclosure (FIG. 9A is a longitudinal sectional view schematically illustrating part of a longitudinal sectional structure of a semiconductor module, and FIG. 9B is a plan view of the semiconductor module).

FIG. 10 is a view illustrating Reference Example 1-2 according to the first embodiment of the technology of this disclosure (FIG. 10A is a longitudinal sectional view schematically illustrating part of a longitudinal sectional structure of a semiconductor module, and FIG. 10B is a plan view of the semiconductor module).

FIG. 11 is a view illustrating Reference Example 1-3 according to the first embodiment of the technology of this disclosure (FIG. 11A is a longitudinal sectional view schematically illustrating part of a longitudinal sectional structure of a semiconductor module, and FIG. 11B is a plan view of the semiconductor module).

FIG. 12 is a view illustrating a result of simulation of a relationship between a surface roughness of a first joined surface portion of a heat sink in a case where the first joined surface portion includes protrusions and the thermal resistance of a thermally-conductive bonding material, in terms of Reference Example 1-1 of FIG. 9, Reference Example 1-2 of FIG. 10, and Reference Example 1-3 of FIG. 11.

FIG. 13 is a view illustrating Reference Example 1-4 according to the first embodiment of the technology of this disclosure (FIG. 13A is a longitudinal sectional view schematically illustrating part of a longitudinal sectional structure of a semiconductor module, and FIG. 13B is a plan view of the semiconductor module).

FIG. 14 is a view illustrating Reference Example 1-5 according to the first embodiment of the technology of this disclosure (FIG. 14A is a longitudinal sectional view schematically illustrating part of a longitudinal sectional structure of a semiconductor module, and FIG. 14B is a plan view of the semiconductor module).

FIG. 15 is a view illustrating Reference Example 1-6 according to the first embodiment of the technology of this disclosure (FIG. 15A is a longitudinal sectional view schematically illustrating part of a longitudinal sectional structure of a semiconductor module, and FIG. 15B is a plan view of the semiconductor module).

FIG. 16 is a view illustrating Reference Example 1-7 according to the first embodiment of the technology of this disclosure (FIG. 16A is a longitudinal sectional view schematically illustrating part of a longitudinal sectional structure of a semiconductor module, and FIG. 16B is a plan view of the semiconductor module).

FIG. 17 is a view illustrating Modified Example 1-1 according to the first embodiment of the technology of this disclosure and is a plan view schematically illustrating a first joined surface portion side of a heat sink,

FIG. 18 is a view illustrating Modified Example 1-2 according to the first embodiment of the technology of this disclosure and is a plan view schematically illustrating a first joined surface portion side of a heat sink.

FIG. 19 is a view illustrating Modified Example 1-3 according to the first embodiment of the technology of this disclosure and is a plan view schematically illustrating a first joined surface portion side of a heat sink.

FIG. 20 is a view illustrating Modified Example 1-4 according to the first embodiment of the technology of this disclosure and is a plan view schematically illustrating a longitudinal sectional structure.

FIG. 21 is a view illustrating Modified Example 1-5 according to the first embodiment of the technology of this disclosure and is a plan view schematically illustrating a longitudinal sectional structure.

FIG. 22 is a view illustrating Modified Example 1-6 according to the first embodiment of the technology of this disclosure and is a plan view schematically illustrating a longitudinal sectional structure.

FIG. 23A is a longitudinal sectional view schematically illustrating a longitudinal sectional structure of a power conversion device according to a second embodiment of the technology of this disclosure;

FIG. 23B is a main longitudinal sectional view illustrating part of FIG. 23A in an enlarged manner;

FIG. 23C is a bottom plan view of a semiconductor module illustrated in FIG. 23A.

FIG. 24 is a view illustrating Modified Example 2-1 according to the second embodiment of the technology of this disclosure and is a bottom plan view of a semiconductor module.

FIG. 25 is a longitudinal sectional view schematically illustrating part of a longitudinal sectional structure of a power conversion device according to a third embodiment of the technology of this disclosure.

### DESCRIPTION OF EMBODIMENTS

With reference to the drawings, the following describes embodiments of the technology of this disclosure.

In the drawings to be referred to in the following description, identical or similar portions have identical or similar reference signs. Note that the drawings are schematic, and a relationship between thickness and flat dimension, a ratio between layer thicknesses, and the like are different from actual ones. Accordingly, a specific thickness or dimension should be determined in consideration of the following description.

Further, it is needless to say that portions having a different relationship or ratio may be included in the drawings.

The effects or advantages described in the present disclosure are just examples and are not limitative, and the technology of this disclosure may achieve other effects or advantages.

The following embodiments illustrate a device or a method to embody the technical idea of the technology of this disclosure and do not limit configurations to the following description. That is, various changes can be added to the technical idea of the technology of this disclosure within a technical scope defined by claims described in Claims.

The definitions of directions such as “up” and “down” in this disclosure are merely definitions for convenience of the description and do not restrict the technical idea of the technology of this disclosure. For example, when a target is rotated by 90° and observed, the “up-down direction” is replaced with the “right-left direction,” and when the target is rotated by 180° and observed, the top and bottom are upside down.

In this disclosure, in three directions perpendicular to each other in a space, a first direction and a second direction perpendicular to each other on the same plane are defined as an X-direction and a Y-direction, and a third direction perpendicular to the first direction and the second direction is defined as a Z-direction. The following embodiments are described with the Z-direction being a thickness direction of a resin sealing body 40 (described later).

In this disclosure, in a case where a transistor put on a transistor chip is a field effect transistor (FET), a static induction transistor (SIT), or the like, a first main electrode indicates either one of a source electrode or a drain electrode, a second main electrode indicates the other one of the electrodes, and a control electrode indicates a gate electrode. In a case where the transistor put on the transistor chip is a bipolar junction transistor (BJT) or the like, the first main electrode indicates either one of an emitter electrode and a collector electrode, the second main electrode indicates the other one of the electrodes, and the control electrode indicates a base electrode. In a case where the transistor put on the transistor chip is an insulated gate bipolar transistor (IGBT) or the like, the first main electrode indicates either one of an emitter electrode and a collector electrode, the second main electrode indicates the other one of the electrodes, and the control electrode indicates a gate electrode. The following embodiments will be described focusing on an IGBT as the transistor put on the transistor chip, and therefore, the first main electrode is an emitter electrode, the second main electrode is a collector electrode, and the control electrode is a gate electrode.

In this disclosure, a plan view refers to a case where an electronic device is viewed from the Z-direction. A sectional view refers to a view of a cross section along the Z-direction as viewed from a direction (the Z-direction) perpendicular to this cross section.

### First Embodiment

A first embodiment deals with an example in which the technology of this disclosure is applied to a power conversion device as an electronic device.

The first embodiment also describes a two-element packaged type (i.e., 2-in-1 type) semiconductor module as a semiconductor module. The 2-in-1 semiconductor module includes two elements each including one set of a semiconductor switching element and a rectifier as one element.

Here, “protrusions, a first recess, and a second recess” in the technology of this disclosure can be provided on at least one of a heat sink side and a heat dissipation plate side of the semiconductor module; however, in the first embodiment, a case where “the protrusions, the first recess, and the second recess” are provided on the heat sink side will be discussed.

### <<Overall Configuration of Power Conversion Device>>

First described is an overall configuration of a power conversion device as an example of the electronic device.

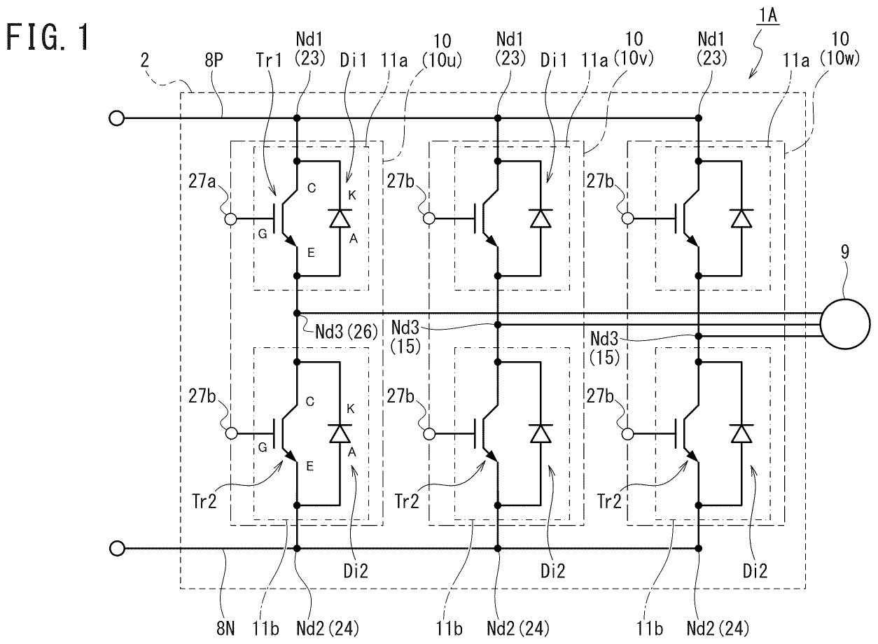

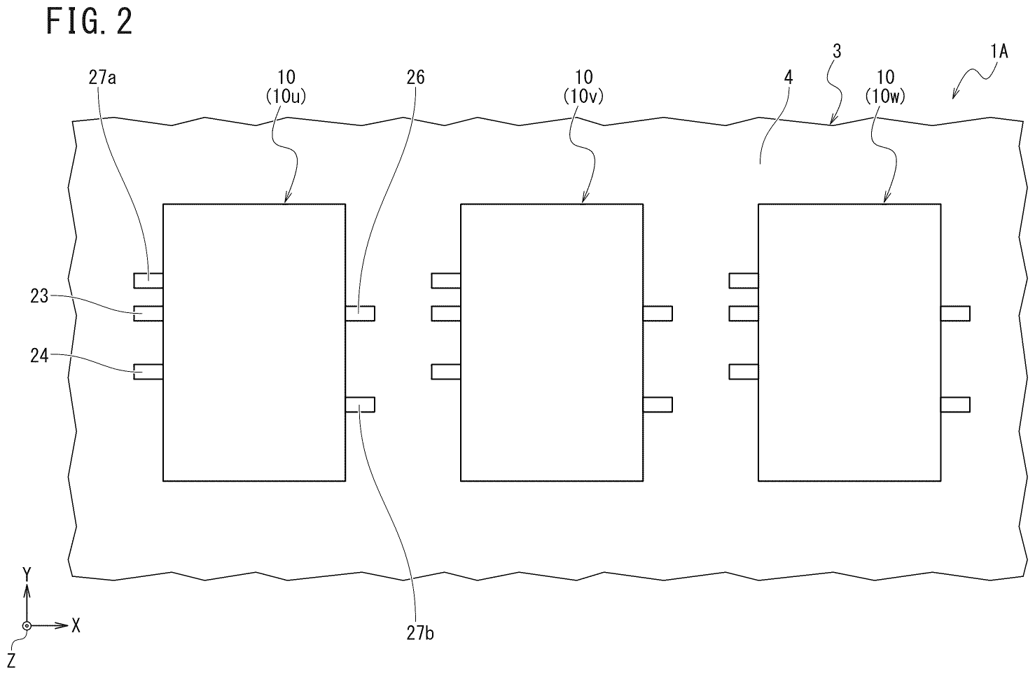

A power conversion device 1A according to the first embodiment of the technology of this disclosure includes an inverter unit 2 illustrated in FIG. 1 and a heat sink 3 illustrated in FIG. 2. The inverter unit 2 converts electric power from direct current into alternating current. The inverter unit 2 is provided on the heat sink 3.

### <Heat Sink>

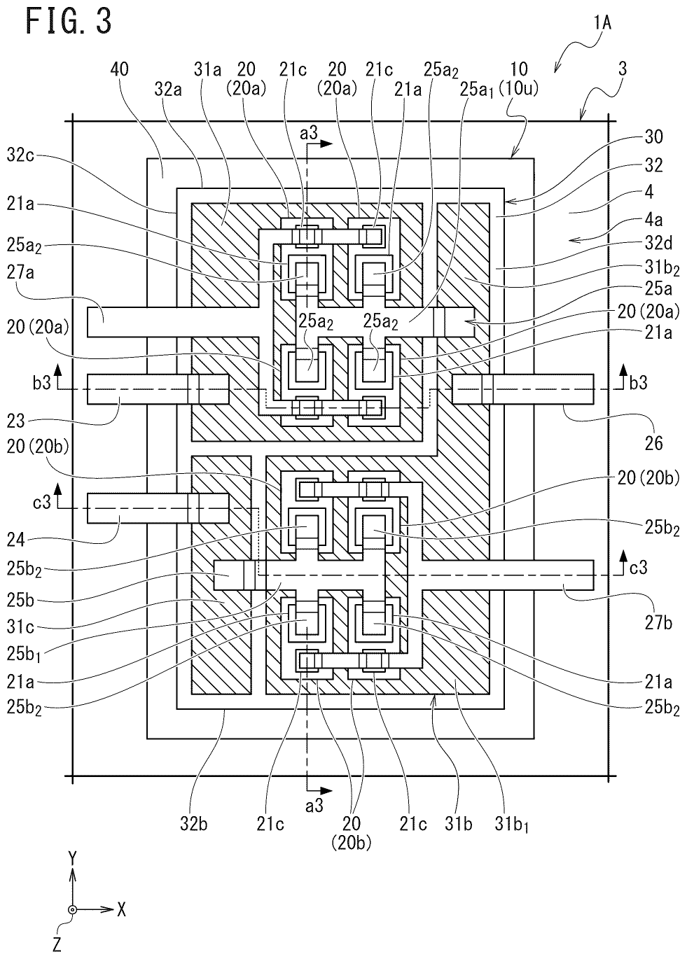

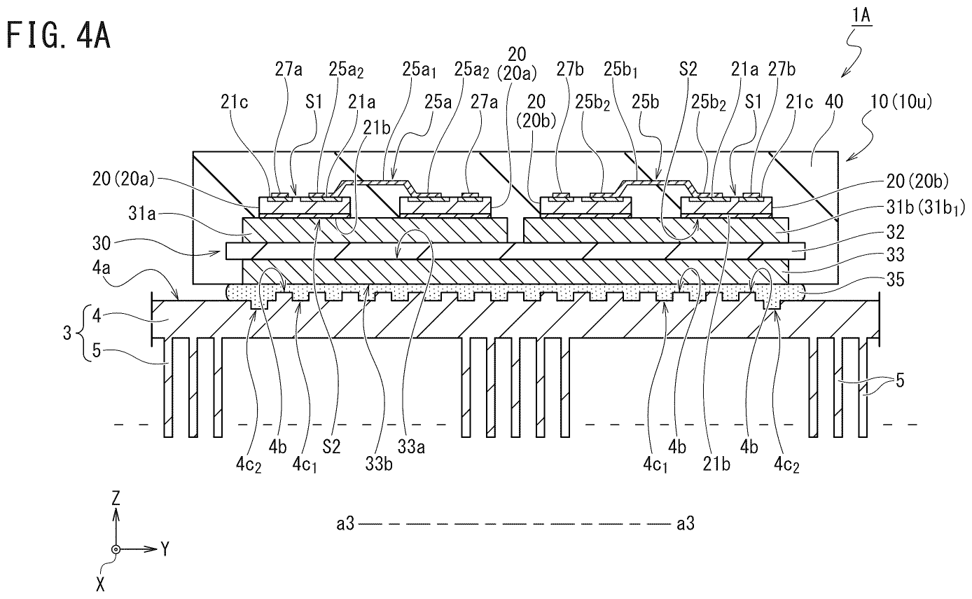

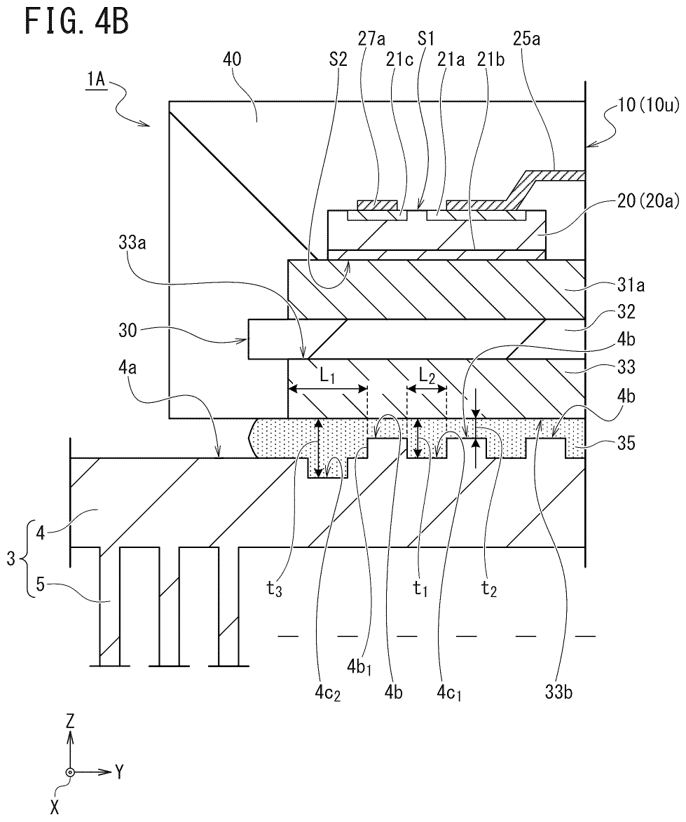

As illustrated in FIG. 3 and FIG. 4A, the heat sink 3 includes a base member 4 including a first joined surface portion 4a, and heat dissipation fins 5 provided on the opposite side to the first joined surface portion 4a of the base member 4 and provided repeatedly at predetermined intervals in the Y-direction. That is, the heat sink 3 includes the first joined surface portion 4a. The heat sink 3 is made of metal or alloy having an excellent heat conductivity, such as copper or aluminum, for example.

### <Inverter Unit>

As illustrated in FIG. 1, the inverter unit 2 includes three semiconductor modules 10 (10u, 10v, 10w), a positive power line 8P, and a negative power line 8N.

The three semiconductor modules 10 (10u, 10v, 10w) are provided to correspond to a U-phase, a V-phase, and a W-phase of a three-phase induction motor 9, for example. Each of the three semiconductor modules 10 (10u, 10v, 10w) is configured such that a switching element Tr1 as an upper arm 11a and a switching element Tr2 as a lower arm 11b are connected in series. In each of the three semiconductor modules 10 (10u, 10v, 10w), a rectifier Di1 is reversely connected in parallel to the switching element Tr1, and a rectifier Di2 is reversely connected in parallel to the switching element Tr2. That is, each of the three semiconductor modules 10 (10u, 10v, 10w) has a one-leg configuration in which two switching elements Tr1 and Tr2 are connected in series. The power conversion device 1A has a six-element three-leg configuration.

Each of IGBTs (as insulated gate bipolar transistors) provided on each of a plurality of transistor chips 20a illustrated in FIG. 3 are connected in parallel to each other to increase the amount of current, for example, although the switching element Tr1 is not limited thereto. Similarly to the switching element Tr1, in the switching element Tr2, each of IGBTs provided on each of a plurality of transistor chips 20b illustrated in FIG. 3 are connected in parallel to each other to increase the current capacity.

Each of free wheel diodes (FWD) provided on each of the plurality of transistor chips 20a illustrated in FIG. 3 are connected in parallel to each other to increase the rectification capacity, for example, although the rectifier Di1 is not limited thereto. Similarly to the rectifier Di1, in the rectifier Di2, each of free wheel diodes (FWD) provided on each of the plurality of transistor chips 20b illustrated in FIG. 3 are connected in parallel to each other to increase the rectification capacity.

As illustrated in FIG. 1, each of the switching elements Tr1 and Tr2 includes an emitter electrode (E) and a collector electrode (C) as a pair of the first main electrode and the second main electrode, and a gate electrode (G) as the control electrode.

In the switching element Tr1, the collector electrode (C) is electrically connected to the positive power line 8P via a first input node Nd1, and the emitter electrode (E) is electrically connected to the collector electrode (C) of the switching element Tr2 via an output node Nd3. The emitter electrode (E) of the switching element Tr2 is electrically connected to the negative power line 8N via a second input node Nd2. That is, the three semiconductor modules 10 (10u, 10v, 10w) are connected in parallel to each other between the positive power line 8P and the negative power line 8N.

In the rectifier Di1, an anode electrode (A) is electrically connected to the emitter electrode (E) of the switching element Tr1, and a cathode electrode (K) is electrically connected to the collector electrode (C) of the switching element Tr1. In the rectifier Di2, an anode electrode (A) is electrically connected to the emitter electrode (E) of the switching element Tr2, and the cathode electrode (K) is electrically connected to the collector electrode (C) of the switching element Tr2.

In response to the gate electrodes (G) of the switching elements Tr1 and Tr2 receiving a gate signal (a control signal) output from a gate drive circuit in each of the three semiconductor modules 10 (10u, 10v, 10w) of the inverter unit 2, a U-phase motor driving current, a V-phase motor driving current, and a W-phase driving current are supplied from respective output nodes Nd3 of the semiconductor modules 10 to motor windings of the three-phase induction motor 9.

### <<Concrete Configuration of Semiconductor Module>>

Next will be described a concrete configuration of a semiconductor module with reference to FIG. 3 to FIG. 8.

The three semiconductor modules 10 (10u, 10v, 10w) have the same configuration. Accordingly, the first embodiment selectively describes the configuration of the semiconductor module 10 with reference to the semiconductor module 10u among the three semiconductor modules 10 (10u, 10v, 10w), and the remaining two semiconductor modules 10 (10v, 10w) are not described herein.

As illustrated in FIG. 3 to FIG. 6, the semiconductor module 10u according to the first embodiment includes a supporting substrate 30, a plurality of transistor chips 20 provided on one surface side of the supporting substrate 30, and a resin sealing body 40 as a sealing body to seal the one surface side of the supporting substrate 30 and the plurality of transistor chips 20. The semiconductor module 10u according to the first embodiment further includes, as leads extending inside and outside the resin sealing body 40, a positive lead 23, a negative lead 24, an output lead 26, and first and second control leads 27a, 27b. The semiconductor module 10u according to the first embodiment further includes first and second relay leads 25a, 25b located inside the resin sealing body 40.

Each of the positive lead 23, the negative lead 24, the output lead 26, and the first and second control leads 27a, 27b includes an inner lead portion located inside the resin sealing body 40 and an outer lead portion located outside the resin sealing body 40, and the outer lead portion located outside the resin sealing body 40 functions as an external terminal. The outer lead portion of the positive lead 23 corresponds to the first input node Nd1 in FIG. 1, the outer lead portion of the negative lead 24 corresponds to the second input node Nd2 in FIG. 1, and the outer lead portion of the output lead 26 corresponds to the output node Nd3 in FIG. 1.

### <Supporting Substrate>

As illustrated in FIG. 3, the supporting substrate 30 is formed in a rectangular planar shape in a plan view, for example, in an oblong shape. The supporting substrate 30 includes two short-side portions opposite from each other in a longitudinal direction along the Y-direction and extending in a short direction along the X-direction perpendicular to the Y-direction, and two long-side portions opposite from each other in the X-direction and extending in the Y-direction. The supporting substrate 30 has a thickness in the Z-direction perpendicular to the X-direction and the Y-direction.

As illustrated in FIG. 3 to FIG. 6, the supporting substrate 30 includes an insulating plate 32 having a main surface portion and a back surface portion opposite to each other in the Z-direction, a first electrically-conductive plate 31a, a second electrically-conductive plate 31b, and a third electrically-conductive plate 31c as electrically-conductive plates provided on the main surface portion side of the insulating plate 32, and a heat dissipation plate 33 provided on the back surface portion side of the insulating plate 32.

As the supporting substrate 30, a direct copper bonding (DCB) substrate including eutectic bonding metals on each of a main surface portion and a back surface portion of a ceramic substrate, the main surface portion and the back surface portion being opposite to each other, an AMB substrate including metal provided by the active metal brazing (AMB) method on each of a main surface portion and a back surface portion of a ceramic substrate, the main surface portion and the back surface portion being opposite to each other, or the like can be used, for example. A material of the ceramic substrate can be, for example, silicon nitride (Si₃N₄), aluminum nitride (AlN), alumina (Al₂O₃), and the like. In the supporting substrate 30 according to the first embodiment, an aluminum nitride plate is used as the insulating plate 32, for example, and a metal plate containing copper (Cu) having an excellent electrical conductivity and an excellent thermal conductivity is used as the electrically-conductive plates (the first to third electrically-conductive plates 31a, 31b, 31c) and the heat dissipation plate 33, for example.

### (Insulating Plate)

As illustrated in FIG. 3, the insulating plate 32 is formed in a rectangular planar shape in a plan view, for example, in an oblong shape. The insulating plate 32 includes a main surface portion and a back surface portion opposite to each other in the Z-direction as the thickness direction of the insulating plate 32. The insulating plate 32 includes two short-side portions 32a and 32b opposite to each other in the Y-direction and extending in the X-direction perpendicular to the Y-direction, and two long-side portions 32c and 32d opposite to each other in the X-direction and extending in the Y-direction. In the first embodiment, two short-side portions 32a and 32b of the insulating plate 32 are two short-side portions of the supporting substrate 30, and two long-side portions 32c and 32d of the insulating plate 32 are two long-side portions of the supporting substrate 30. Accordingly, in the first embodiment, the two short-side portions of the supporting substrate 30 may be referred to as the short-side portions 32a and 32b. Also, the two long-side portions of the supporting substrate 30 may be referred to as the long-side portions 32c and 32d.

### (Electrically-Conductive Plate)

As illustrated in FIG. 3, the first electrically-conductive plate 31a is placed on the short-side portion 32a side of the insulating plate 32 and on the long-side portion 32c side of the insulating plate 32 in a plan view. The first electrically-conductive plate 31a has a rectangular shape in a plan view.

As illustrated in FIG. 3, the second electrically-conductive plate 31b includes a first portion 31b1 placed on the short-side portion 32b side of the insulating plate 32 and on the long-side portion 32c side of the insulating plate 32 in a plan view, and a second portion 31b2 integrated with the first portion 31b1 and placed between the first electrically-conductive plate 31a and the long-side portion 32d of the insulating plate 32 in a plan view. The first portion 31b1 of the second electrically-conductive plate 31b has a rectangular shape in a plan view. The second portion 31b2 of the second electrically-conductive plate 31b extends from the first portion 31b1 toward the short-side portion 32a of the insulating plate 32. The second electrically-conductive plate 31b is electrically and structurally (physically) separated from the first electrically-conductive plate 31a.

As illustrated in FIG. 3, the third electrically-conductive plate 31c is placed between the long-side portion 32c of the insulating plate 32 and the first portion 31b1 of the second electrically-conductive plate 31b. The third electrically-conductive plate 31c extends along the Y-direction. The third electrically-conductive plate 31c is electrically and structurally (physically) separated from the first electrically-conductive plate 31a and the second electrically-conductive plate 31b.

Each of the first electrically-conductive plate 31a, the second electrically-conductive plate 31b, and the third electrically-conductive plate 31c has a main surface portion and a back surface portion opposite to each other in the Z-direction, and their back surface portion sides are joined to the main surface portion side of the insulating plate 32.

### (Heat Dissipation Plate)

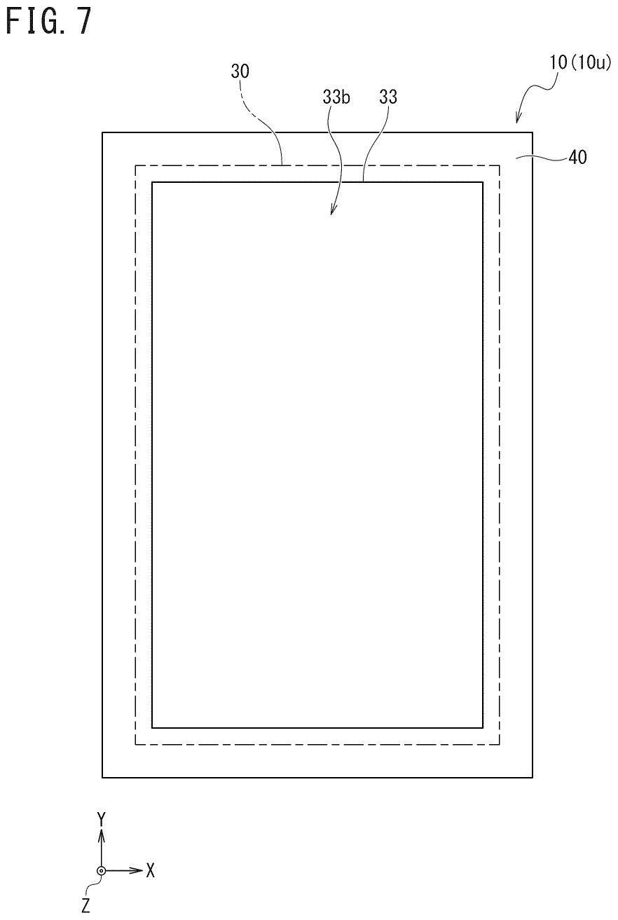

As illustrated in FIG. 7, the heat dissipation plate 33 has a rectangular planar shape in a plan view similarly to the insulating plate 32 and has an external shape size slightly smaller than the external shape size of the insulating plate 32. As illustrated in FIG. 4A to FIG. 6, the heat dissipation plate 33 overlaps with the first electrically-conductive plate 31a, the second electrically-conductive plate 31b, and the third electrically-conductive plate 31c in a plan view.

As illustrated in FIG. 4A to FIG. 7, the heat dissipation plate 33 includes a main surface portion 33a and a second joined surface portion (back surface portion) 33b opposite to each other. The main surface portion 33a side of the heat dissipation plate 33 is joined to the back surface portion side of the insulating plate 32, and the second joined surface portion 33b side of the heat dissipation plate 33 is exposed from a back surface portion side of the resin sealing body 40 out of a main surface portion (an upper surface portion) and a back surface portion (a bottom surface portion) of the resin sealing body 40, the main surface portion and the back surface portion being opposite to each other.

### (Transistor Chip)

As illustrated in FIG. 3, the plurality of transistor chips 20 includes a plurality of transistor chips 20a provided on the first electrically-conductive plate 31a on one surface side of the supporting substrate 30, and a plurality of transistor chips 20b provided on the second electrically-conductive plate 31b on the one surface side of the supporting substrate 30. For example, four transistor chips 20a are arranged in 2×2 on the first electrically-conductive plate 31a, and four transistor chips 20b are arranged in 2×2 on the second electrically-conductive plate 31b, although the first embodiment is not limited to this.

Each of the four transistor chips 20a and the four transistor chips 20b includes, as a transistor, a vertical-structure insulated gate bipolar transistor (IGBT), for example. Respective transistors provided on the four transistor chips 20a are connected in parallel to each other and constitute the switching element Tr1 illustrated in FIG. 1. Each of transistors provided on the four transistor chips 20b is also connected in parallel to each other and constitute the switching element Tr2 illustrated in FIG. 1.

Each of the four transistor chips 20a and the four transistor chips 20b includes, as a diode, a vertical-structure free wheel diode (FWD), for example. Respective diodes provided on the four transistor chips 20a are connected in parallel to each other and constitute the rectifier Di1 illustrated in FIG. 1. Respective diodes provided on the four transistor chips 20b are also connected in parallel to each other and constitute the rectifier Di2 illustrated in FIG. 1.

The four transistor chips 20a and the four transistor chips 20b structurally have the same configuration. More specifically, with reference to FIG. 4A, each of the four transistor chips 20a and the four transistor chips 20b includes a first surface portion S1 and a second surface portion S2 opposite to each other, a first main electrode 21a and a control electrode 21c provided on the first surface portion S1 side, and a second main electrode 21b provided on the second surface portion S2 side.

In the first embodiment, the first main electrode 21a functions as an emitter electrode, the second main electrode 21b functions as a collector electrode, and the control electrode 21c functions as a gate electrode. Although not illustrated herein, an emitter region of the IGBT provided on the transistor chip 20 (20a, 20b) and an anode region of the FWD provided thereon are electrically connected to the first main electrode 21a. A collector region of the IGBT provided on the transistor chip 20 (20a, 20b) and a cathode region of the FWD provided thereon are electrically connected to the second main electrode 21b. A gate electrode of the IGBT provided on the transistor chip 20 (20a, 20b) is electrically connected to the control electrode 21c. Each of the first main electrode 21a and the control electrode 21c is made of an aluminum (Al) film or an alloy film mainly containing Al, for example. The second main electrode 21 is made of a copper (Cu) film or an alloy film mainly containing Cu, for example.

Each of the four transistor chips 20a and the four transistor chips 20b is constituted by a semiconductor chip mainly including a substrate made of a wideband gap semiconductor such as SiC or GaN, for example. It is preferable that the IGBT and the FWD have a vertical structure in which a principal current flows in the thickness direction (the depth direction: the Z-direction) of the transistor chip 20a, 20b.

Referring now to FIG. 4A and FIG. 4B, each of the four transistor chips 20a is provided on the first electrically-conductive plate 31a in such a manner that the second main electrode 21b is joined to one surface of the first electrically-conductive plate 31a which one surface is opposite to the insulating plate 32 side via an electrically-conductive bonding material (e.g., a solder material). That is, the second main electrodes 21b of the four transistor chips 20a are electrically and mechanically connected to the first electrically-conductive plate 31a and are connected in parallel to each other via the first electrically-conductive plate 31a.

Further, each of the four transistor chips 20b is provided on the second electrically-conductive plate 31b in such a manner that the second main electrode 21b is joined to one surface of the second electrically-conductive plate 31b which one surface is opposite to the insulating plate 32 side via an electrically-conductive bonding material (for example, a solder material). That is, the second main electrodes 21b of the four transistor chips 20b are electrically and mechanically connected to the second electrically-conductive plate 31b and are connected in parallel to each other via the second electrically-conductive plate 31b.

### (Resin Sealing Body)

As illustrated in FIG. 2 and FIG. 3, the resin sealing body 40 is formed in a square planar shape in a plan view, for example, in an oblong shape. The resin sealing body 40 includes two short-side portions opposite to each other in a longitudinal direction along the Y-direction and extending in a short direction along the X-direction perpendicular to the Y-direction, and two long-side portions opposite to each other in the Y-direction and extending in the X-direction.

As illustrated in FIG. 3, the extending direction of the two short-side portions of the resin sealing body 40 coincides with the extending direction of the two short-side portions 32a, 32b of the supporting substrate 30 (the insulating plate 32). The extending direction of the two long-side portions of the resin sealing body 40 coincides with the extending direction of the two long-side portions 32c, 32d of the supporting substrate 30 (the insulating plate 32).

As illustrated in FIG. 3 to FIG. 7, the resin sealing body 40 seals the plurality of transistor chips 20 provided on the one surface side of the supporting substrate 30 such that the second joined surface portion 33b of the heat dissipation plate 33 is exposed. The resin sealing body 40 covers the outer periphery of the heat dissipation plate 33 and the plurality of transistor chips 20.

The resin sealing body 40 has a thickness in the Z-direction perpendicular to the X-direction and the Y-direction and includes a main surface portion and a back surface portion opposite to each other in the Z-direction. The resin sealing body 40 can be molded by transfer molding using epoxy-based thermosetting insulating resin, for example.

### (Positive Lead)

As illustrated in FIG. 3, the positive lead 23 is placed on the long-side portion 32c side out of the two long-side portions 32c, 32d of the supporting substrate 30 (the insulating plate 32) in a plan view in such a manner as to extend into the resin sealing body 40.

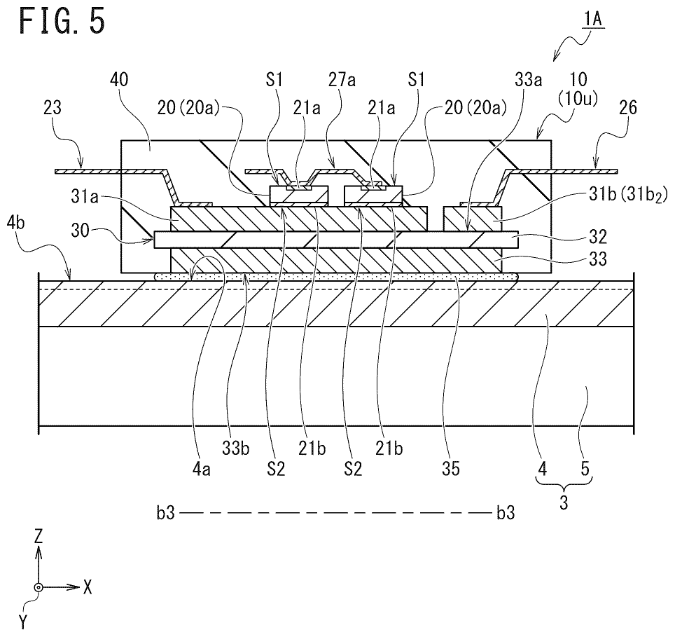

As illustrated in FIG. 3 and FIG. 5, the positive lead 23 includes an inner lead portion located inside the resin sealing body 40 and having a gull wing shape, and an outer lead portion side of the positive lead 23 is offset from a distal end side of the inner lead portion thereof in height position in the thickness direction (the Z-direction) of the resin sealing body 40. The distal end side of the inner lead portion of the positive lead 23 is joined to one surface side of the electrically-conductive plate 31a via an electrically-conductive bonding material, so that the positive lead 23 is electrically and mechanically connected to the first electrically-conductive plate 31a. That is, the positive lead 23 is electrically connected to the second main electrodes 21b of the four transistor chips 20a via the first electrically-conductive plate 31a. The positive lead 23 is electrically connected to the positive power line 8P illustrated in FIG. 1 although not illustrated here in detail.

### (First Relay Lead)

As illustrated in FIG. 3 and FIG. 4A, the first relay lead 25a includes a main portion 25a1 extending between the first electrically-conductive plate 31a and the second portion 31b2 of the second electrically-conductive plate 31b in a plan view, and four branch portions 25a2 integrated with the main portion 25a1 and individually overlapping with respective first main electrodes 21a of the four transistor chips 20a in a plan view.

A distal end side of the main portion 25a1, which is opposite to the branch portion 25a2 side in the longitudinal direction, is formed in a gull wing shape, and is offset from the branch portion 25a2 side in height position in the thickness direction (the Z-direction) of the resin sealing body 40. The distal end side of the main portion 25a1 is joined to one surface side of the second portion 31b2 of the second electrically-conductive plate 31b via an electrically-conductive bonding material, so that the main portion 25a1 is electrically and mechanically connected to the second electrically-conductive plate 31b.

Each of the four branch portions 25a2 is formed in a gull wing shape, so that the main portion 25a1 is offset from a distal end side of each of the four branch portions 25a2 in height position in the thickness direction (the Z-direction) of the resin sealing body 40. Each of the four branch portions 25a2 is individually joined to the first main electrode 21a of a corresponding one of the four transistor chips 20a via an electrically-conductive bonding material and is electrically and mechanically connected to the first main electrode 21a. That is, the first main electrodes 21a of the four transistor chips 20a are electrically connected to each other via the first relay lead 25a.

### (Second Relay Lead)

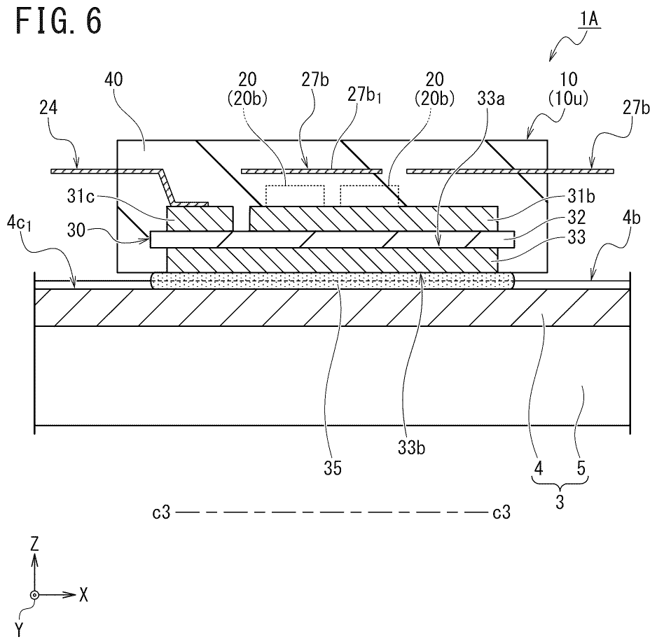

As illustrated in FIG. 3, FIG. 4A, and FIG. 6, the second relay lead 25b includes a main portion 25b1 extending between the first portion 31b1 of the second electrically-conductive plate 31b and the third electrically-conductive plate 31c in a plan view, and four branch portions 25b2 integrated with the main portion 25b1 and individually overlapping with respective first main electrodes 21a of the four transistor chips 20b in a plan view.

A distal end side of the main portion 25b1 which distal end side is opposite to the branch portion 25b2 side in the longitudinal direction has a gull wing shape, and the distal end side is offset from the branch portion 25b2 side in height position in the thickness direction (the Z-direction) of the resin sealing body 40. The distal end side of the main portion 25b1 is joined to one surface side of the third electrically-conductive plate 31c via an electrically-conductive bonding material, so that the main portion 25b1 is electrically and mechanically connected to the third electrically-conductive plate 31c.

Each of the four branch portions 25b2 has a gull wing shape, so that the main portion 25b1 is offset from a distal end side of each of the four branch portions 25b2 in height position in the thickness direction (the Z-direction) of the resin sealing body 40. Each of the four branch portions 25b2 is individually joined to the first main electrode 21a of a corresponding one of the four transistor chips 20b via an electrically-conductive bonding material and is electrically and mechanically connected to the first main electrode 21a. That is, the first main electrodes 21a of the four transistor chips 20b are electrically connected to each other via the second relay lead 25b.

### (Negative Lead)

As illustrated in FIG. 3, the negative lead 24 is placed on the long-side portion 32c side out of the two long-side portions 32c, 32d of the supporting substrate 30 (the insulating plate 32) in a plan view.

As illustrated in FIG. 3 and FIG. 6, the negative lead 24 includes an inner lead portion located inside the resin sealing body 40 and having a gull wing shape, and an outer lead portion side of the negative lead 24 is offset from a distal end side of the inner lead portion thereof in height position in the thickness direction (the Z-direction) of the resin sealing body 40. The distal end side of the inner lead portion of the negative lead 24 is joined to one surface side of the third electrically-conductive plate 31c via an electrically-conductive bonding material, so that the negative lead 24 is electrically and mechanically connected to the third electrically-conductive plate 31c. That is, the negative lead 24 is electrically connected to the first main electrodes 21a of the four transistor chips 20b via the first electrically-conductive plate 31a and the second relay lead 25b. The negative lead 24 is electrically connected to the negative power line 8N illustrated in FIG. 1 although not illustrated here in detail.

### (Output Lead)

As illustrated in FIG. 3, the output lead 26 is arranged on the long-side portion 32d side out of the two long-side portions 32c, 32d of the supporting substrate 30 (the insulating plate 32) in a plan view.

As illustrated in FIG. 3 and FIG. 5, the output lead 26 includes an inner lead portion located inside the resin sealing body 40 and being formed in a gull wing shape, and an outer lead portion side of the output lead 26 is offset from a distal end side of the inner lead portion thereof in height position in the thickness direction (the Z-direction) of the resin sealing body 40. The distal end side of the inner lead portion of the output lead 26 is joined to one surface side of the second portion 31b2 of the second electrically-conductive plate 31b via an electrically-conductive bonding material, so that the output lead 26 is electrically and mechanically connected to the second electrically-conductive plate 31b. That is, the output lead 26 is electrically connected to the first main electrodes 21a of the four transistor chips 20a on the upper arm 11a side via the second electrically-conductive plate 31b. The output lead 26 is electrically connected to the first main electrodes 21a of the four transistor chips 20b on the lower arm 11b side via the second electrically-conductive plate 31b. The output lead 26 is connected to motor windings of the three-phase induction motor 9 or the like illustrated in FIG. 1, although not illustrated here in detail.

### (First Control Lead)

As illustrated in FIG. 3, the first control lead 27a is provided across the long-side portion 32c as one long-side portion out of the two long-side portions 32c, 32d of the supporting substrate 30 (the insulating plate 32) in a plan view in such a manner as to extend inside and outside the resin sealing body 40.

The first control lead 27a is routed such that an inner lead portion thereof located inside the resin sealing body 40 overlaps with the control electrodes 21c of the four transistor chips 20a included in the upper arm 11a. The inner lead portion of the first control lead 27a includes gull-wing-shape portions, and respective joined portions of the gull-wing-shape portions are joined to respective control electrodes 21c of the four transistor chips 20a via electrically-conductive bonding materials in such a manner as to be electrically and mechanically connected to the control electrodes 21c. The joined portions of the inner lead portion of the first control lead 27a are offset from an outer lead portion thereof in height position in the thickness direction (the Z-direction) of the resin sealing body 40.

### (Second Control Lead)

As illustrated in FIG. 3, the second control lead 27b is provided across the long-side portion 32d as the other long-side portion out of the two long-side portions 32c, 32d of the supporting substrate 30 (the insulating plate 32) in a plan view in such a manner as to extend inside and outside the resin sealing body 40, for example, although the second control lead 27b is not limited to this.

The second control lead 27b is routed such that an inner lead portion thereof located inside the resin sealing body 40 overlaps with the control electrodes 21c of the four transistor chips 20b included in the lower arm 11b. The inner lead portion of the second control lead 27b includes gull-wing-shape portions, and respective joined portions of the gull-wing-shape portions are joined to respective control electrodes 21c of the four transistor chips 20b via electrically-conductive bonding materials in such a manner as to be electrically and mechanically connected to the control electrode 21c. The joined portions of the inner lead portion of the second control lead 27b are offset from an outer lead portion thereof in height position in the thickness direction (the Z-direction) of the resin sealing body 40.

### (Material of Leads)

The positive lead 23, the negative lead 24, the first and second relay leads 25a, 25b, the output lead 26, and the first and second control leads 27a, 27b are made of iron (Fe)—nickel (Ni) alloy having an excellent electrical conductivity and an excellent thermal conductivity, for example.

### (Parallel Connection of Transistor Chips)

As described above, the second main electrodes 21b of the four transistor chips 20a on the upper arm 11a side are electrically connected to each other via the first electrically-conductive plate 31a. The first main electrodes 21a of the four transistor chips 20a are also electrically connected to each other via the first relay lead 25a. Accordingly, the four transistor chips 20a are connected in parallel to each other on a side of the heat dissipation plate 33 which is opposite to the second joined surface portion 33b.

As described above, the second main electrodes 21b of the four transistor chips 20b on the lower arm 11b side are electrically connected to each other via the second electrically-conductive plate 31b. The first main electrodes 21a of the four transistor chips 20b are also electrically connected to each other via the second relay lead 25b. Accordingly, the four transistor chips 20b are connected in parallel to each other on a side of the heat dissipation plate 33, which is opposite to the second joined surface portion 33b.

### <<Concrete Configuration of First Joined Surface Portion>>

Next will be described a concrete configuration of the first joined surface portion 4a of the heat sink 3.

As illustrated in FIG. 4A and FIG. 4B, the semiconductor module 10u includes the heat dissipation plate 33 including the second joined surface portion 33b joined to the first joined surface portion 4a of the heat sink 3 (the base member 4) via the thermally-conductive bonding material 35, and the plurality of transistor chips 20 connected in parallel to each other on a side of the heat sink, which is opposite to the second joined surface portion 33b.

In the first embodiment, out of the first joined surface portion 4a of the heat sink 3 and the second joined surface portion 33b of the heat dissipation plate 33, the first joined surface portion 4a of the heat sink 3 includes protrusions 4b, first recesses 4c₁, and second recesses 4c₂. The second joined surface portion 33b of the heat dissipation plate 33 is uniformly flat.

More specifically, in an overlapping region where the first joined surface portion 4a of the heat sink 3 overlaps with the second joined surface portion 33b of the heat dissipation plate 33 in a plan view, the first joined surface portion 4a of the heat sink 3 includes a plurality of protrusions 4b protruding toward the second joined surface portion 33b side of the heat dissipation plate 33, the first recess 4c₁ placed between two adjacent protrusions 4b and recessed in a direction away from the second joined surface portion 33b side of the heat dissipation plate 33, and the second recess 4c₂ placed outward of the plurality of protrusions 4b and recessed in a direction away from the second joined surface portion 33b side of the heat dissipation plate 33. That is, in the overlapping region where the first joined surface portion 4a of the heat sink 3 overlaps with the second joined surface portion 33b of the heat dissipation plate 33 in a plan view, the first joined surface portion 4a of the heat sink 3 has a recessed-protruding shape (rough shape) including the protrusions 4b, the first recesses 4c₁, and the second recesses 4c₂.

As illustrated in FIG. 4B, a thickness (film thickness) t₁ at the first recess 4c₁ of the thermally-conductive bonding material 35 is greater than a thickness (film thickness) t₂ thereof at the protrusion 4b. A thickness (film thickness) t₃ at the second recess 4c₂ of the thermally-conductive bonding material 35 is greater than the thickness (film thickness) t₁ at the first recess 4c₁. That is, the thermally-conductive bonding material 35 has the thicknesses ty, t₂, t₃ to satisfy “t₃>t₁>t₂” between the first joined surface portion 4a of the heat sink 3 and the second joined surface portion 33b of the heat dissipation plate 33.

As illustrated in FIG. 4B, a distance L₁ from an outer side wall 4b₁ of an outermost protrusion 4b among the plurality of protrusions 4b to an outer edge (a side surface portion) of the heat dissipation plate 33 is longer than a distance L₂ (the width of the first recess 4c₁) between two adjacent protrusions 4b.

Here, the thickness t₁ of the thermally-conductive bonding material 35 at the first recess 4c₁ is a thickness (a film thickness) between the second joined surface portion 33b of the heat dissipation plate 33 and a bottom surface portion of the first recess 4c₁. The thickness t₂ of the thermally-conductive bonding material 35 at the protrusion 4b is a thickness (a film thickness) between the second joined surface portion 33b of the heat dissipation plate 33 and an upper surface portion of the protrusion 4b. The thickness t₃ of the thermally-conductive bonding material 35 at the second recess 4c₂ is a thickness (a film thickness) between the second joined surface portion 33b of the heat dissipation plate 33 and a bottom surface portion of the second recess 4c₂. In other words, in the thermally-conductive bonding material 35, the thickness (the film thickness) t₃ between the second joined surface portion 33b and the bottom surface portion of the second recess 4c₂ is greater than the thickness (the film thickness) t₁ between the second joined surface portion 33b and the bottom surface portion of the first recess 4c₁, and the thickness (the film thickness) t₁ between the second joined surface portion 33b and the bottom surface portion of the first recess 4c₁ is greater than the thickness (the film thickness) t₂ between the second joined surface portion 33b and the protrusion 4b (t₃>t₁>t₂).

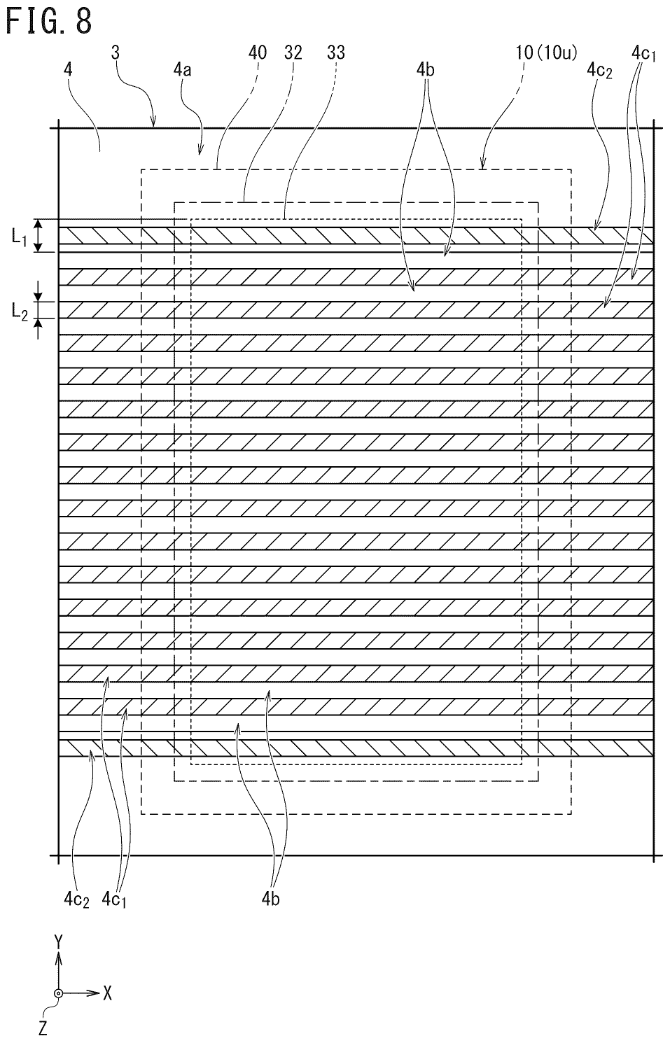

As illustrated in FIG. 8, the protrusions 4b, the first recesses 4c₁, and the second recesses 4c₂ are aligned in the Y-direction and extend linearly in the X-direction. The protrusions 4b, the first recesses 4c₁, and the second recess 4c₂ extend inside and outside the semiconductor module 10u in a plan view across the semiconductor module 10u. In the first embodiment, as illustrated in FIG. 2, three semiconductor modules 10 (10u, 10v, 10w) are aligned in the X-direction with their longitudinal directions being along the Y-direction, and therefore, the protrusions 4b, the first recesses 4c₁, and the second recesses 4c₂ are provided across the three semiconductor modules 10 (10u, 10v, 10w) one after another in a plan view.

In the first embodiment, in the thermally-conductive bonding material 35, it is preferable that the thickness t₃ at the second recess 4c₂ be equal to or more than 150 μm and the thickness t₂ at the protrusion 4b be equal to or less than 50 μm, for example. The thermally-conductive bonding material 35 can be a solder material, a sintered material, an adhesive, or the like having an excellent thermal conductivity and an excellent bonding property, for example.

In the first embodiment, as illustrated in FIG. 4A to FIG. 6, the thermally-conductive bonding material 35 is provided over the heat dissipation plate 33 and the resin sealing body 40 in a plan view.

It is noted that the protrusion 4b can be expressed in other words as a “protrusion 4b protruding from a reference surface of the first joined surface portion 4a toward the second joined surface portion 33b side.”

The first recess 4c₁ can be expressed in other words as a “first recess 4c₁ extending from the upper surface portion of the protrusion 4b toward a side opposite to the second joined surface portion 33b side.”

The second recess 4c₂ can be expressed in other words as a “second recess 4c₂ extending from the reference surface of the first joined surface portion 4a toward a side opposite to the second joined surface portion 33b side.”

The first recess 4c₁ and the second recess 4c₂ can be also expressed in other words as a first groove 4c₁ and a second groove 4c₂.

### Main Effects of First Embodiment

Next will be described main effects of the first embodiment.

As described above, in the power conversion device 1A according to the first embodiment, the second joined surface portion 33b of the heat dissipation plate 33 of the semiconductor module 10 is joined to the first joined surface portion 4a of the heat sink 3 via the thermally-conductive bonding material 35, as described above. The first joined surface portion 4a of the heat sink 3 includes the plurality of protrusions 4b protruding toward the second joined surface portion 33b side of the heat dissipation plate 33, the first recesses 4c₁ each placed between the protrusions 4b and recessed in a direction away from the second joined surface portion 33b side of the heat dissipation plate 33, and the second recesses 4c₂ placed outward of the plurality of protrusions 4b and recessed in a direction away from the second joined surface portion 33b side of the heat dissipation plate 33. In the thermally-conductive bonding material 35, the thickness (film thickness) t₁ at the first recess 4c₁ is greater than the thickness (film thickness) t₂ at the protrusion 4b, and the thickness (film thickness) t₃ at the second recess 4c₂ is greater than the thickness (film thickness) t₁ at the first recess 4c₁ (t₃>t₁>t₂).

With such a configuration, in terms of the heat dissipation function (transfer function) of the thermally-conductive bonding material 35 that dissipates heat generated by the semiconductor module 10 from the heat dissipation plate 33 of the semiconductor module 10 to the heat sink 3, since the thickness (film thickness) t₂ of the thermally-conductive bonding material 35 at the protrusion 4b is lesser than the thickness (film thickness) t₁ thereof at the first recess 4c₁, the heat dissipation function of the thermally-conductive bonding material 35 at the protrusion 4b can be made higher than the heat dissipation function thereof at the first recess 4c₁.

In the meantime, in terms of the joining function (peeling resistance and breakage resistance) of the thermally-conductive bonding material 35 to relax stress caused in the thermally-conductive bonding material 35 and to join the second joined surface portion 33b of the heat dissipation plate 33 of the semiconductor module 10 to the first joined surface portion 4a of the heat sink 3, since the thickness (film thickness) t₁ of the thermally-conductive bonding material 35 at the first recess 4c₁ is greater than the thickness (film thickness) t₂ thereof at the protrusion 4b, the joining function of the thermally-conductive bonding material 35 at the first recess 4c₁ can be made higher than the joining function thereof at the protrusion 4b. Since the thickness (film thickness) t₃ of the thermally-conductive bonding material 35 at the second recess 4c₂ is greater than the thickness (film thickness) t₁ thereof at the first recess 4c₁, the joining function of the thermally-conductive bonding material 35 at the second recess 4c₂ can be made higher than the joining function thereof at the first recess 4c₁.

That is, the heat dissipation function of the thermally-conductive bonding material 35 can be enhanced at the protrusion 4b, and the joining function of the thermally-conductive bonding material 35 can be enhanced at the first recess 4c₁ and the second recess 4c₂, thereby making it possible to improve the heat dissipation function and the joining function of the thermally-conductive bonding material 35. Accordingly, the electronic device 1A according to the first embodiment of the technology of this disclosure can improve both the reliability and the heat dissipation property.

Particularly, the stress to be caused in the thermally-conductive bonding material 35 is higher in a peripheral portion of the heat dissipation plate 33 than a central portion of the heat dissipation plate 33 in a plan view. In the meantime, the temperature of the heat dissipation plate 33 due to heat generation of the transistor chip 20 is higher in the central portion of the heat dissipation plate 33 than in the peripheral portion of heat dissipation plate 33 in a plan view. Accordingly, with the second recesses 4c₂ being arranged outward of the plurality of protrusions 4b like the first embodiment, it is possible to further improve the joining function while the heat dissipation function is secured at an equivalent level, in comparison with a case where no second recess 4c₂ is provided.

Further, the thermally-conductive bonding material 35 is reduced in thickness by the protrusions 4b, thereby making is possible to reduce the used amount of the thermally-conductive bonding material 35. This accordingly makes it possible to achieve a reduction in cost of the electronic device 1A.

Particularly, in the two-element packaged type (2-in-1 type) semiconductor module 10 like the first embodiment, the plane external shape size of the heat dissipation plate 33 is larger than that of a heat dissipation plate of a one-element packaged type (1-in-1 type), and therefore, an effect achieved by reducing the used amount of the thermally-conductive bonding material 35 is large in the first embodiment.

In the electronic device 1A according to the first embodiment, the distance L₁ from the outer side wall 4b₁ of the outermost protrusion 4b among the plurality of protrusions 4b to the outer edge of the heat dissipation plate 33 is longer than the distance L₂ between two adjacent protrusions 4b. With such a configuration, since the joining function of the thermally-conductive bonding material 35 can be made further higher in the peripheral portion (outside the plurality of protrusions 4b) of the heat dissipation plate 33, it is possible to give weight to the heat dissipation function of the thermally-conductive bonding material 35 in the central portion of the heat dissipation plate 33 (a region where the plurality of protrusions 4b and the first recesses 4c₁ are provided) and to give weight to the joining function of the thermally-conductive bonding material 35 in the peripheral portion of the heat dissipation plate 33.

Particularly, peeling easily occurs on the peripheral portion side of the heat dissipation plate 33 under the influence of a warp of the heat sink 3 or a warp of the heat dissipation plate 33, and therefore, it is important to enhance the joining function of the thermally-conductive bonding material 35 in the peripheral portion of the heat dissipation plate 33.

In the electronic device 1A according to the first embodiment, the protrusions 4b, the first recesses 4c₁, and the second recesses 4c₂ are aligned in the Y-direction and extend linearly in the X-direction. With such a configuration, the protrusions 4b, the first recesses 4c₁, and the second recesses 4c₂ can be easily formed on the heat sink 3 by casting or press working. Further, respective widths of the protrusions 4b, the first recesses 4c₁, and the second recesses 4c₂ can be changed easily.

In the electronic device 1A according to the first embodiment, the protrusions 4b, the first recesses 4c₁, and the second recesses 4c₂ are provided across the semiconductor modules 10 in a plan view. With such a configuration, gas generated from the thermally-conductive bonding material 35 is easily released at the time when the second joined surface portion 33b of the heat dissipation plate 33 of the semiconductor module 10 is joined to the first joined surface portion 4a of the heat sink 3 via the thermally-conductive bonding material 35, so that it is possible to restrain the occurrence of voids and to improve a joining quality and a heat dissipation quality of the thermally-conductive bonding material 35.

In the electronic device 1A according to the first embodiment, the thermally-conductive bonding material 35 is provided over the heat dissipation plate 33 and the resin sealing body 40 in a plan view. With such a configuration, it is possible to increase a joining area between the thermally-conductive bonding material 35 and the heat sink 3 and to expand a heat transfer range from the heat dissipation plate 33 to the heat sink 3 in a planer direction (the lateral direction), thereby making it possible to improve cooling performance for the semiconductor module 10.

<Relationship between Surface Roughness of First Joined Surface Portion and Thermal Resistance>

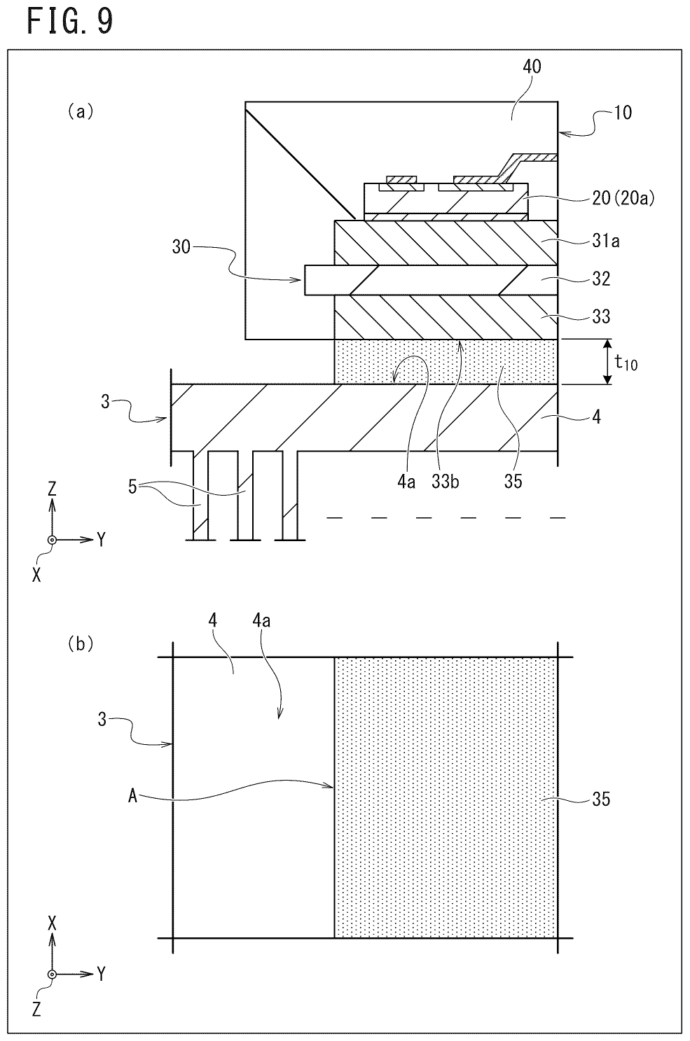

Next will be described a relationship between the surface roughness (recesses and protrusions) of the first joined surface portion 4a of the heat sink 3 and the thermal resistance of the thermally-conductive bonding material 35 with reference to FIG. 9 to FIG. 12.

FIG. 9 is a view illustrating Reference Example 1-1 (FIG. 9A is a longitudinal sectional view schematically illustrating part of a longitudinal sectional structure of a semiconductor module, and FIG. 9B is a plan view thereof).

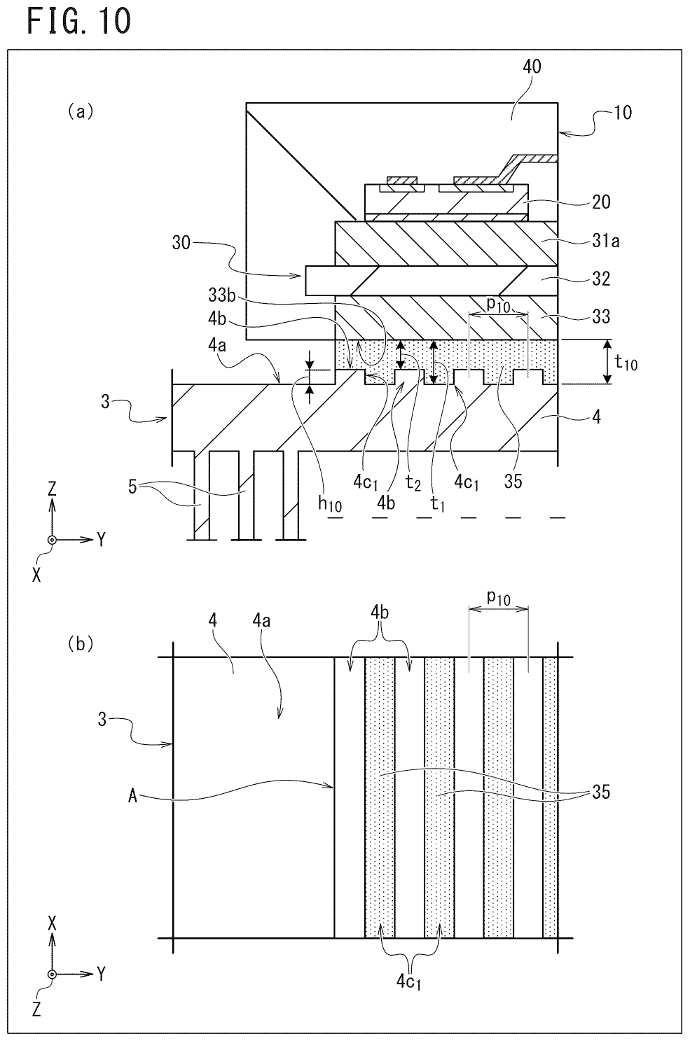

FIG. 10 is a view illustrating Reference Example 1-2 (FIG. 10A is a longitudinal sectional view schematically illustrating part of a longitudinal sectional structure of a semiconductor module, and FIG. 10B is a plan view thereof).

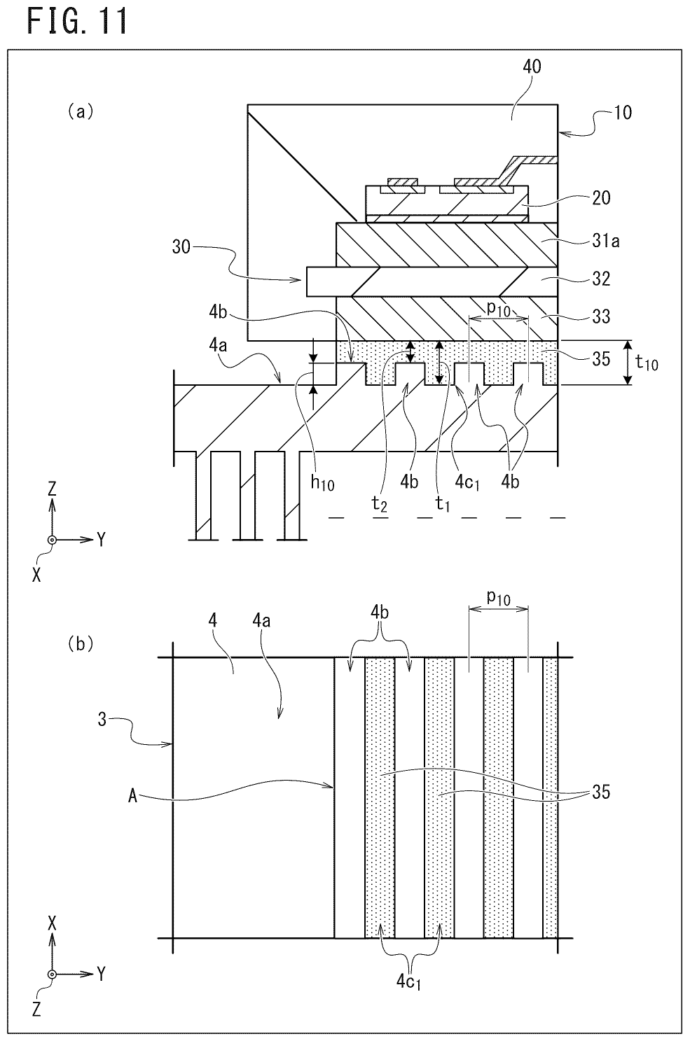

FIG. 11 is a view illustrating Reference Example 1-3 (FIG. 11A is a longitudinal sectional view schematically illustrating part of a longitudinal sectional structure of a semiconductor module, and FIG. 11B is a plan view thereof).

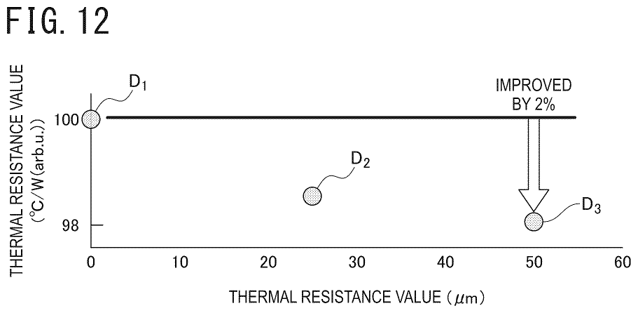

FIG. 12 is a view illustrating a result of simulation of a relationship between a surface roughness Rz (μm) of the first joined surface portion 4a of the heat sink 3 and a thermal resistance (° C./W) of the thermally-conductive bonding material 35 in a case where the first joined surface portion 4a includes the protrusions 4b, in terms of each of Reference Example 1-1 of FIG. 9, Reference Example 1-2 of FIG. 10, and Reference Example 1-3 of FIG. 11.

It is noted that, in FIG. 10B and FIG. 11B, the thermally-conductive bonding material 35 at the first recess 4c₁ between two protrusions 4b is illustrated selectively so that the protrusions 4b are easily observable.

In Reference Example 1-1 of FIG. 9, the first joined surface portion 4a of the heat sink 3 and the second joined surface portion 33b of the heat dissipation plate 33 of the semiconductor module 10 are both flat, and the thermally-conductive bonding material 35 has a uniform thickness to. The thickness t₁₀ of the thermally-conductive bonding material 35 is about 150 μm, and the thermally-conductive bonding material 35 has a volume of around 288.176 mm³ in a region A where the first joined surface portion 4a of the heat sink 3 overlaps with the second joined surface portion 33b of the heat dissipation plate 33 in a plan view.

In Reference Example 1-2 of FIG. 10, in the same region A as in Reference Example 1-1, the first joined surface portion 4a of the heat sink 3 includes the protrusions 4b provided repeatedly with a predetermined arrangement pitch p₁₀ in the Y-direction. The thickness t₁₀ of the thermally-conductive bonding material 35 is about 150 μm similarly to Reference Example 1-1, the protrusions 4b have a height h₁₀ of around 30 μm, and the arrangement pitch p₁₀ between the protrusions 4b is around 100 μm. In Reference Example 1-2, the thermally-conductive bonding material 35 has a volume of around 244.9496 mm³ in the region A. The thickness t₂ of the thermally-conductive bonding material 35 at the protrusion 4b is a value obtained by subtracting the height h₁₀ of the protrusion 4b from the thickness t₁₀ of the thermally-conductive bonding material and is thinner than the thickness t₁ at the first recess 4c₁ between two protrusions 4b.

In Reference Example 1-3 of FIG. 11, in the same region A as in Reference Example 1-1, the first joined surface portion 4a of the heat sink 3 includes the protrusions 4b provided repeatedly with the same arrangement pitch p₁₀ as in Reference Example 1-1. The thickness t₁₀ of the thermally-conductive bonding material 35 is about 150 μm, which is the same as in Reference Example 1-1, and the height h₁₀ of the protrusion 4b is 50 μm, which is higher than in Reference Example 1-2. In Reference Example 1-3, the thermally-conductive bonding material 35 has a volume of around 216.32 mm³ in the region A.

In FIG. 12, D₁ indicates data in Reference Example 1-1 in FIG. 9, D₂ indicates data in Reference Example 1-2 in FIG. 10, and D₃ indicates data in Reference Example 1-3 in FIG. 11.

As is apparent from the simulation result in FIG. 12, the thermal resistance of the thermally-conductive bonding material 35 is smaller in in Reference Example 1-2 in FIG. 10 and Reference Example 1-3 in FIG. 11, in which the first joined surface portion 4a of the heat sink 3 includes the protrusions 4b, than in Reference Example 1-1 in FIG. 9, in which the first joined surface portion 4a of the heat sink 3 is flat.

The thermal resistance of the thermally-conductive bonding material 35 is smaller in Reference Example 1-3 in FIG. 11, in which the height of the protrusion 4b is higher than that in Reference Example 1-2 in FIG. 10. In Reference Example 1-3 in FIG. 11, the thermal resistance of the thermally-conductive bonding material 35 is improved by about 2% in comparison with Reference Example 1-1 in FIG. 9.

In view of this, with reference to FIG. 4B, it is confirmed that, when the first joined surface portion 4a of the heat sink 3 includes the protrusions 4b and the first recesses 4c₁, the heat dissipation function of the thermally-conductive bonding material 35 can be improved.

The volume of the thermally-conductive bonding material 35 in the region A is smaller in Reference Example 1-2 in FIG. 10 and Reference Example 1-3 in FIG. 11, in which the first joined surface portion 4a of the heat sink 3 includes the protrusions 4b, than in Reference Example 1-1 in FIG. 9, in which the first joined surface portion 4a of the heat sink 3 is flat. The volume of the thermally-conductive bonding material 35 in the region A in Reference Example 1-3 in FIG. 11, in which the height h₁₀ of the protrusion 4b is 50 μm, is smaller than that in Reference Example 1-2 in FIG. 10, in which the height h₁₀ of the protrusion 4b is 30 μm. The volume of the thermally-conductive bonding material 35 in the region A in Reference Example 1-1 is 388.176 mm³, the volume of the thermally-conductive bonding material 35 in the region A in Reference Example 1-2 is 244.9496 mm³, and the volume of the thermally-conductive bonding material 35 in the region A in Reference Example 1-3 is 216.32 mm³, as described above.

In view of this, with reference to FIG. 4B, it is confirmed that, when the first joined surface portion 4a of the heat sink 3 includes the protrusions 4b and the first recesses 4c₁, the used amount of the thermally-conductive bonding material 35 can be reduced.

### <Relationship Between Recesses and Protrusions of First Joined Surface Portion and Stress to be Cause in Thermally-Conductive Bonding Material>

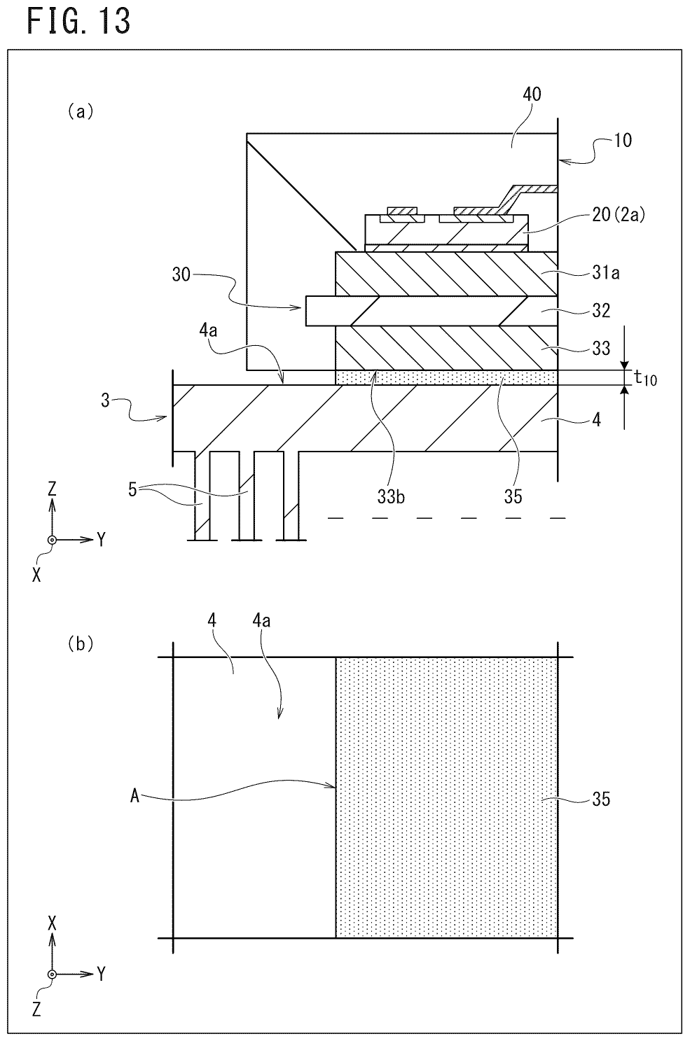

Next will be described a relationship between recesses and protrusions of the first joined surface portion 4a of the heat sink 3 and stress (a.u.) caused in the thermally-conductive bonding material 35 with reference to FIG. 13 to FIG. 16.

FIG. 13 is a view illustrating Reference Example 1-4 according to the first embodiment of the technology of this disclosure (FIG. 13A is a longitudinal sectional view schematically illustrating part of a longitudinal sectional structure of a semiconductor module, and FIG. 13B is a plan view thereof).

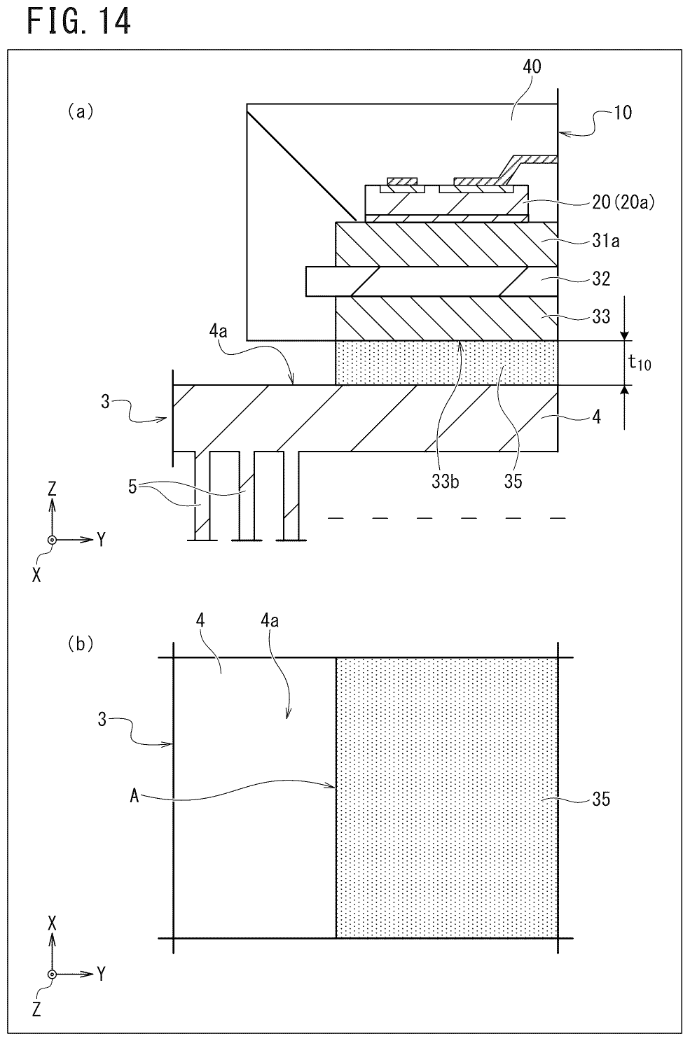

FIG. 14 is a view illustrating Reference Example 1-5 according to the first embodiment of the technology of this disclosure (FIG. 14A is a longitudinal sectional view schematically illustrating part of a longitudinal sectional structure of a semiconductor module, and FIG. 14B is a plan view thereof).

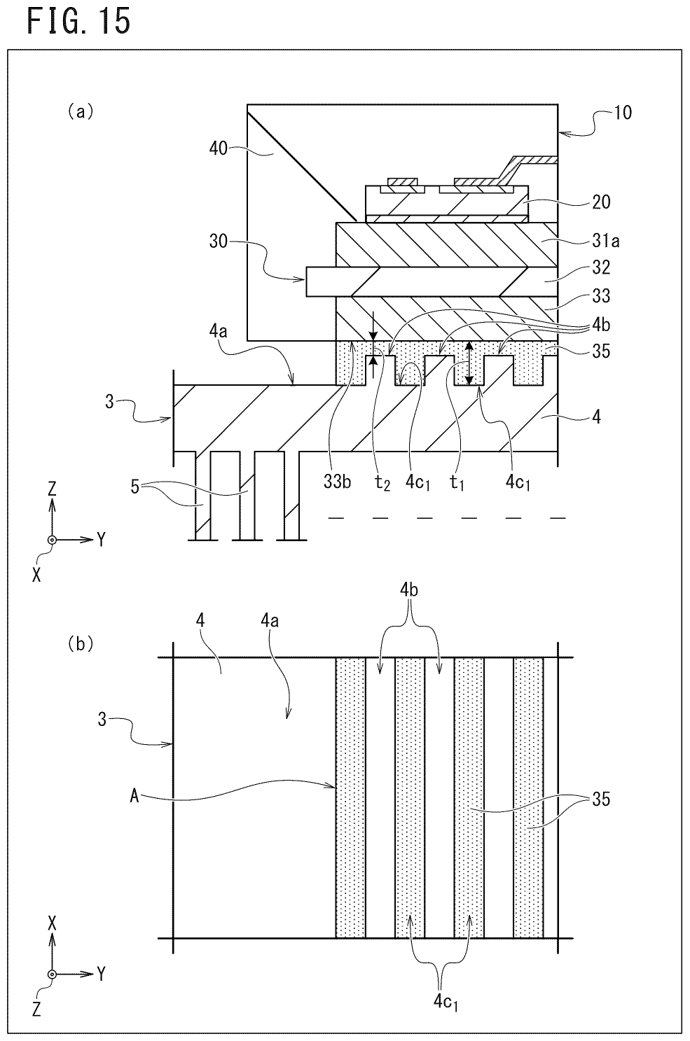

FIG. 15 is a view illustrating Reference Example 1-6 according to the first embodiment of the technology of this disclosure (FIG. 15A is a longitudinal sectional view schematically illustrating part of a longitudinal sectional structure of a semiconductor module, and FIG. 15B is a plan view thereof).

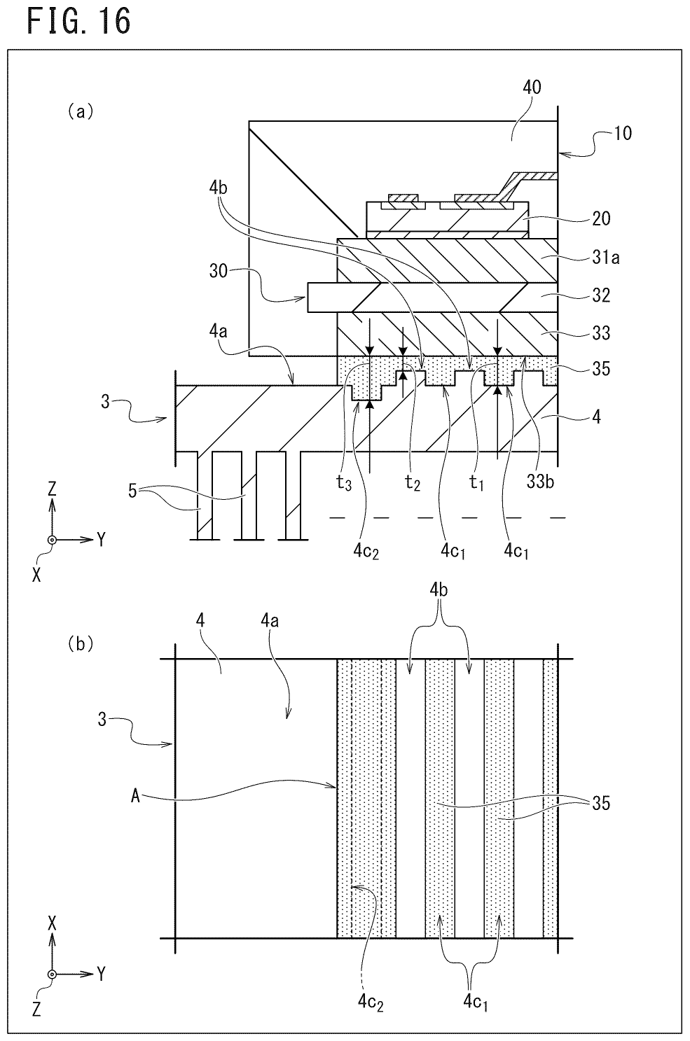

FIG. 16 is a view illustrating Reference Example 1-7 according to the first embodiment of the technology of this disclosure (FIG. 16A is a longitudinal sectional view schematically illustrating part of a longitudinal sectional structure of a semiconductor module, and FIG. 16B is a plan view thereof).

Note that, in FIG. 15B and FIG. 16B, the thermally-conductive bonding material 35 in the first recess 4c₁ between two protrusions 4b is illustrated selectively.

In Reference Example 1-4 of FIG. 13, each of the first joined surface portion 4a of the heat sink 3 and the second joined surface portion 33b of the heat dissipation plate 33 of the semiconductor module 10 is uniformly flat, the thickness t₁₀ of the thermally-conductive bonding material 35 in the region A having the same plane size as in Reference Example 1-1 is 100 μm, and a stress (a.u.) to be caused in the thermally-conductive bonding material 35 is 1.00.

Example 1-5 in FIG. 14 has generally the same configuration as Reference Example 1-4, except that the thickness t₁₀ of the thermally-conductive bonding material 35 is about 150 μm. In Reference Example 1-5, a stress (a.u.) to be caused in the thermally-conductive bonding material 35 is 0.82.

In Reference Example 1-6 of FIG. 15, in the region A having the same area as in Reference Example 1-5, the first joined surface portion 4a of the heat sink 3 includes the protrusions 4b provided repeatedly with a predetermined arrangement pitch in the Y-direction. The first recess 4c₁ is placed between two protrusions 4b. The thickness t₁ of the thermally-conductive bonding material 35 at the first recess 4c₁ is 150 μm, and the thickness t₂ of the thermally-conductive bonding material 35 at the protrusion 4b is 50 μm. A stress (a.u.) to be caused in the thermally-conductive bonding material 35 is 0.89.

In Reference Example 1-7 of FIG. 16, similarly to Reference Example 1-5, in the region A, the first joined surface portion 4a of the heat sink 3 includes the protrusions 4b provided repeatedly with a predetermined arrangement pitch in the Y-direction. The first recess 4c₁ is placed between two protrusions 4b, and the second recesses 4c₂ are placed outward of the plurality of protrusions 4b. The thickness t₁ of the thermally-conductive bonding material 35 at the first recess 4c₁ is about 100 μm, the thickness t₂ of the thermally-conductive bonding material 35 at the protrusion 4b is about 50 μm, and the thickness t₃ of the thermally-conductive bonding material 35 at the second recess 4c₂ is about 150 μm. A stress (a.u.) to be caused in the thermally-conductive bonding material 35 is 0.78. Reference Example 1-7 corresponds to the first embodiment of the technology of this disclosure.

In terms of Reference Example 1-4 in FIG. 13 and Reference Example 1-5 in FIG. 14, in which the first joined surface portion 4a of the heat sink 3 is flat, the stress (a.u.) caused in the thermally-conductive bonding material 35 in Reference Example 1-4 in FIG. 13 is “1.00,” and the stress (a.u.) caused in the thermally-conductive bonding material 35 in Reference Example 1-5 in FIG. 14 is “0.82.” That is, the stress (a.u.) caused in the thermally-conductive bonding material 35 is smaller in Reference Example 1-5 in FIG. 14, in which the thickness t₁₀ of the thermally-conductive bonding material 35 is thicker than that in Reference Example 1-4 in FIG. 13.

In terms of Reference Example 1-5 in FIG. 14, in which the first joined surface portion 4a of the heat sink 3 is uniformly flat, and Reference Example 1-6 in FIG. 15, in which the first joined surface portion 4a of the heat sink 3 includes the protrusions 4b and the first recesses 4c₁, the stress (a.u.) caused in the thermally-conductive bonding material 35 in Reference Example 1-5 in FIG. 14 is “0.82,” and the stress (a.u.) caused in the thermally-conductive bonding material 35 in Reference Example 1-6 in FIG. 15 is “0.89.” That is, the stress (a.u.) caused in the thermally-conductive bonding material 35 is larger in Reference Example 1-6 in FIG. 15, in which the first joined surface portion 4a of the heat sink 3 includes the protrusions 4b and the first recesses 4c₁, than in Reference Example 1-5 in FIG. 14, in which the first joined surface portion 4a of the heat sink 3 is uniformly flat.

In terms of Reference Example 1-6 in FIG. 15, in which the first joined surface portion 4a of the heat sink 3 includes the protrusions 4b and the first recesses 4c₁, and Reference Example 1-7 in FIG. 16, in which the first joined surface portion 4a of the heat sink 3 includes the protrusions 4b, the first recesses 4c₁, and the second recesses 4c₁, the stress (a.u.) caused in the thermally-conductive bonding material 35 in Reference Example 1-6 in FIG. 15 is “0.89,” and the stress (a.u.) caused in the thermally-conductive bonding material 35 in Reference Example 1-7 in FIG. 16 is “0.78.” That is, the stress (a.u.) caused in the thermally-conductive bonding material 35 is smaller in Reference Example 1-7 in FIG. 16, in which the first joined surface portion 4a of the heat sink 3 includes the protrusions 4b, the first recesses 4c₁, and the second recesses 4c₂, than in Reference Example 1-6 in FIG. 15, in which the first joined surface portion 4a of the heat sink 3 includes the protrusions 4b and the first recesses 4c₁.

In view of this, with reference to FIG. 4B, it is confirmed that, when the first joined surface portion 4a of the heat sink 3 includes the protrusions 4b, the first recesses 4c₁, and the second recesses 4c₂, and the thickness t₁ of the thermally-conductive bonding material 35 at the first recess 4c₁ and the thickness t₃ thereof at the second recess 4c₂ are made thicker than the thickness t₂ thereof at the protrusion 4b, it is possible to improve the joining function of the thermally-conductive bonding material 35.

It is confirmed that, due to the improvement in the joining function of the thermally-conductive bonding material 35 from Reference Example 1-4 to Reference Example 1-7 and the improvement in the heat dissipation function from Reference Example 1-1 to Reference Example 1-3, the power conversion device 1A according to the first embodiment is effectively more improved in the reliability and the heat dissipation property.

It is noted that the first embodiment deals with the resin sealing body 40 as the sealing body of the semiconductor module, but the technology of this disclosure is also applicable to a case where a ceramic sealing body is used as the sealing body.

### MODIFIED EXAMPLES OF FIRST EMBODIMENT

The following describes modified examples of the first embodiment.

### Modified Example 1-1

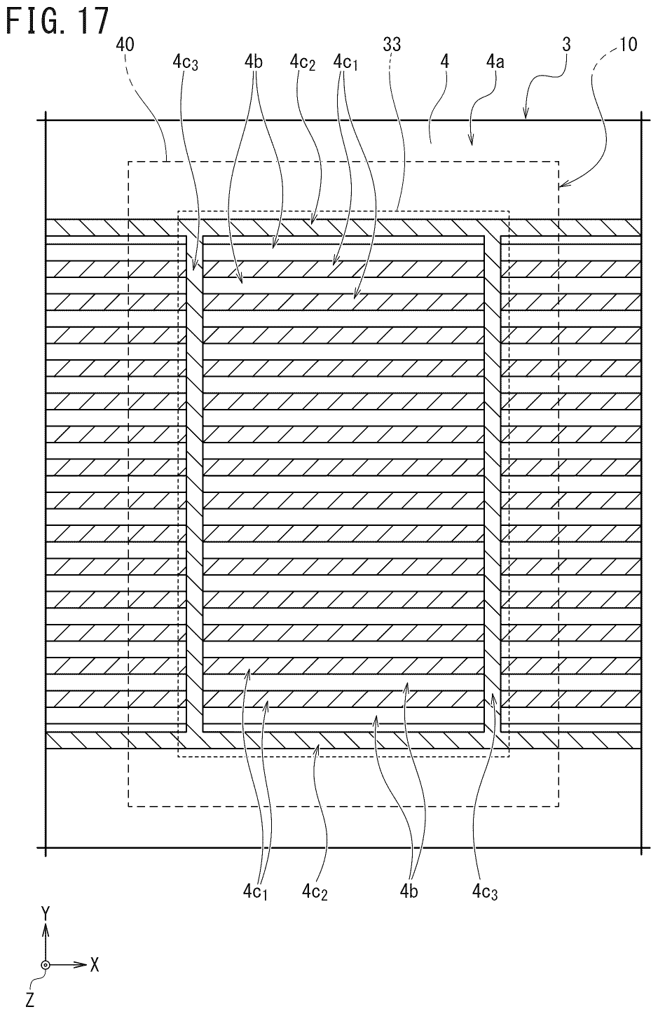

FIG. 17 is a view illustrating Modified Example 1-1 according to the first embodiment of the technology of this disclosure and is a plan view schematically illustrating a first joined surface portion side of a heat sink.

As illustrated in FIG. 17, Modified Example 1-1 basically has a configuration similar to the first embodiment described above but is different from the first embodiment in the configuration of the first joined surface portion 4a of the heat sink 3.

That is, as illustrated in FIG. 17, the first joined surface portion 4a of the heat sink 3 according to Modified Example 1-1 further includes third recesses 4c₃ extending in the Y-direction. Although not illustrated here in detail, the third recesses 4c₃ are recessed to a side opposite to the second joined surface portion 33b side of the heat dissipation plate 33, similarly to the second recess 4c₂ illustrated in FIG. 4B, for example. The third recess 4c₃ has a depth similar to that of the second recess 4c₂, for example. A thickness at the third recess 4c₃ of the thermally-conductive bonding material 35 is greater than the thickness t₁ at the first recess 4c₁, similarly to the thickness t₃ at the second recess 4c₂.

As illustrated in FIG. 17, the third recesses 4c₃ are placed on two long-side portion sides of the heat dissipation plate 33 along the two long-side portions in a region overlapping with the heat dissipation plate 33 in a plan view. The third recesses 4c₃ are provided across the protrusions 4b and the first recesses 4c₁ repeatedly provided in the Y-direction to intersect with the protrusions 4b and the first recesses 4c₁. The third recesses 4c₃ are connected to the second protrusions 4c₂ placed outward of the plurality of protrusions 4b in the region overlapping with the heat dissipation plate 33 in a plan view.

Modified Example 1-1 can also yield effects similar to those of the first embodiment.

Further, in Modified Example 1-1, the first joined surface portion 4a of the heat sink 3 further includes the third recesses 4c₃, thereby making it possible to enhance the joining function of the thermally-conductive bonding material 35 in the peripheral portion of the heat dissipation plate 33 more than the first embodiment described above.

It is noted that the depth of the third recess 4c₃ may be shallower than the second recess 4c₂ or may be deeper than the second recess 4c₂.

### Modified Example 1-2

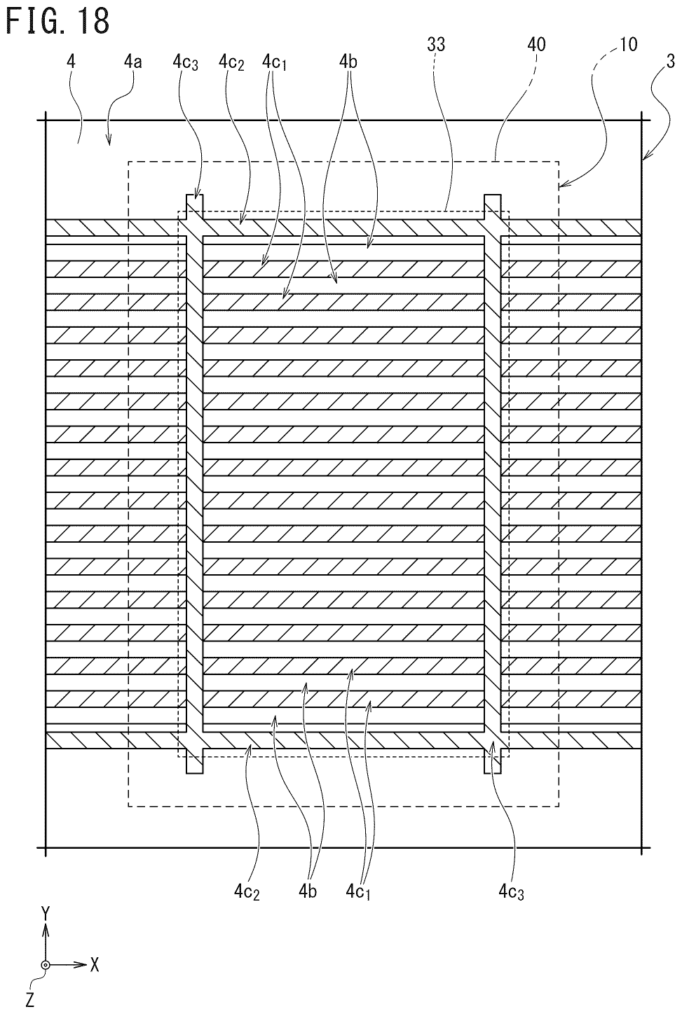

FIG. 18 is a view illustrating Modified Example 1-2 according to the first embodiment of the technology of this disclosure and is a plan view schematically illustrating the first joined surface portion side of the heat sink.

As illustrated in FIG. 18, in Modified Example 1-2, the third recesses 4c₃ in Modified Example 1-1 illustrated in FIG. 17 intersect with the second recesses 4c₂.

Modified Example 1-2 can also yield effects similar to those of the first embodiment and can enhance the joining function of the thermally-conductive bonding material 35 in the peripheral portion of the heat dissipation plate 33 more than the first embodiment, similarly to Modified Example 1-1.

### Modified Example 1-3

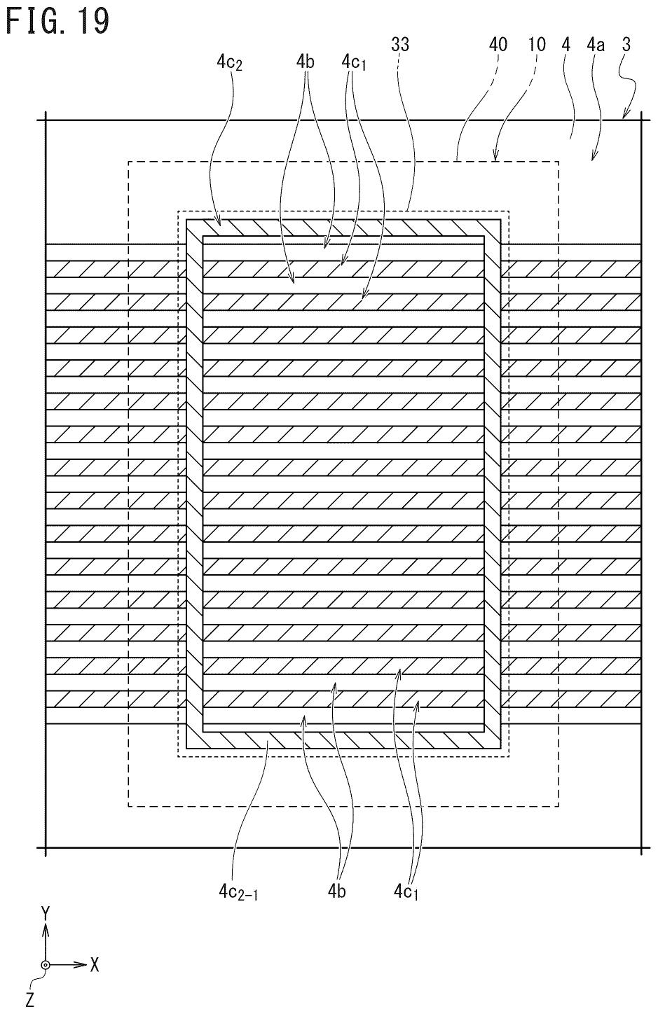

FIG. 19 is a view illustrating Modified Example 1-3 according to the first embodiment of the technology of this disclosure and is a plan view schematically illustrating the first joined surface portion side of the heat sink.

Modified Example 1-3 basically has a configuration similar to the first embodiment described above but is different from the first embodiment in the planar shape of the second recess 4c₂, as illustrated in FIG. 19.

That is, the planar shape of the second recess 4c₂ in Modified Example 1-3 in a plan view has a frame shape (an annular shape) continuously extending along four side portions (two long-side portions and two short-side portions) of the heat dissipation plate 33.

Modified Example 1-3 can also yield effects similar to those of the first embodiment and can also enhance the joining function of the thermally-conductive bonding material 35 in the peripheral portion of the heat dissipation plate 33 more than the first embodiment, similarly to Modified Example 1-1.

### Modified Example 1-4

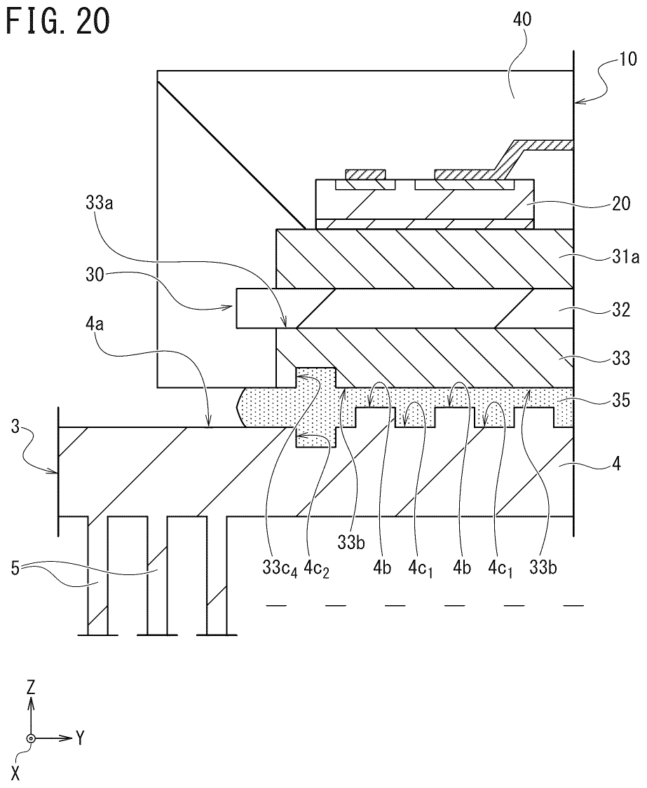

FIG. 20 is a view illustrating Modified Example 1-4 according to the first embodiment of the technology of this disclosure and is a plan view schematically illustrating a longitudinal sectional structure.

Modified Example 1-4 basically has a configuration similar to the first embodiment described above but is different from the first embodiment in the configuration of the second joined surface portion 33b of the heat dissipation plate 33, as illustrated in FIG. 20.

That is, as illustrated in FIG. 20, the second joined surface portion 33b of the heat dissipation plate 33 according to Modified Example 1-4 includes a fourth recess 33c₄ recessed in a direction away from the first joined surface portion 3a side of the heat sink 3. The fourth recess 33c₄ is placed at a position overlapping with the second recess 4c₂ in a plan view and extends along the X-direction similarly to the second recess 4c₂.

Modified Example 1-4 can also yield effects similar to those of the first embodiment.

Further, in Modified Example 1-4, the second joined surface portion 33b of the heat dissipation plate 33 includes the fourth recess 33c₄ overlapping with the second recess 4c₂ of the heat sink 3 in a plan view, so that the thickness of the thermally-conductive bonding material 35 at the second recess 4c₂ and the fourth recess 33c₄ can be made thicker than the thickness t₃ thereof only at the second recess 4c₂ as illustrated in the first embodiment, thereby making it possible to enhance the joining function of the thermally-conductive bonding material 35 in the peripheral portion of the heat dissipation plate 33 more than the first embodiment described above.

### Modified Example 1-5

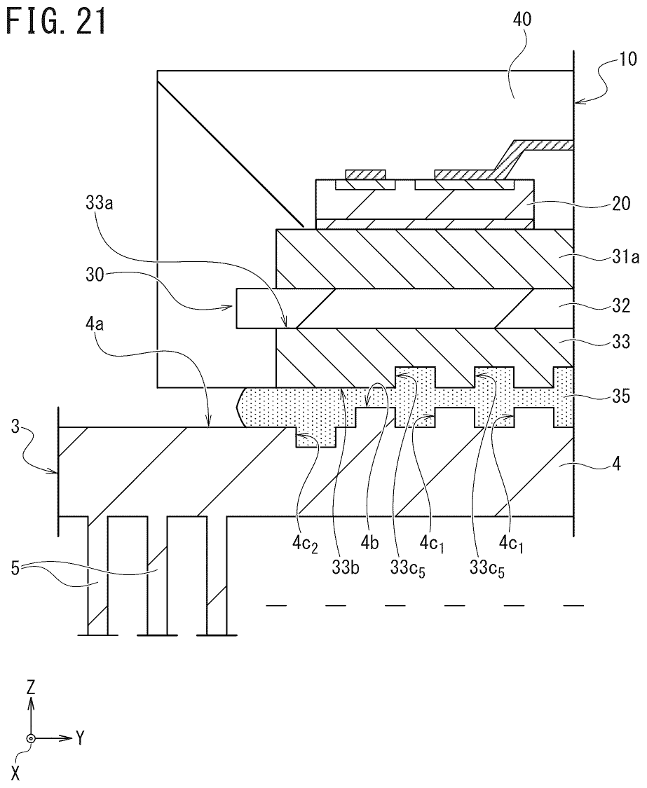

FIG. 21 is a view illustrating Modified Example 1-5 according to the first embodiment of the technology of this disclosure and is a plan view schematically illustrating a longitudinal sectional structure.

Modified Example 1-5 basically has a configuration similar to the first embodiment described above but is different from the first embodiment in the configuration of the second joined surface portion 33b of the heat dissipation plate 33, as illustrated in FIG. 21.

That is, as illustrated in FIG. 21, the second joined surface portion 33b of the heat dissipation plate 33 according to Modified Example 1-5 includes fifth recesses 33c₅ recessed in a direction away from the first joined surface portion 3a side of the heat sink 3. The fifth recesses 33c₅ are placed at positions overlapping with the first recesses 4c₁ in a plan view and extend along the X-direction similarly to the first recesses 4c₁.

Modified Example 1-5 can also yield effects similar to those of the first embodiment.

Further, in Modified Example 1-5, the second joined surface portion 33b of the heat dissipation plate 33 includes the fifth recesses 33c₅ overlapping with the first recesses 4c₁ of the heat sink 3 in a plan view, so that the thickness of the thermally-conductive bonding material 35 at the first recess 4c₁ and the fifth recess 33c₅ can be made thicker than the thickness t₁ thereof only at the first recess 4c₁ as illustrated in the first embodiment, thereby making it possible to enhance the joining function of the thermally-conductive bonding material 35 in the central portion of the heat dissipation plate 33 more than the first embodiment described above.

It is noted that, in Modified Example 1-5, the number of fifth recesses 33c₅ provided herein is the same as the number of first recesses 4c₁, but the number of fifth recesses 33c₅ does not need to be necessarily the same as the number of first recesses 4c₁.

### Modified Example 1-6

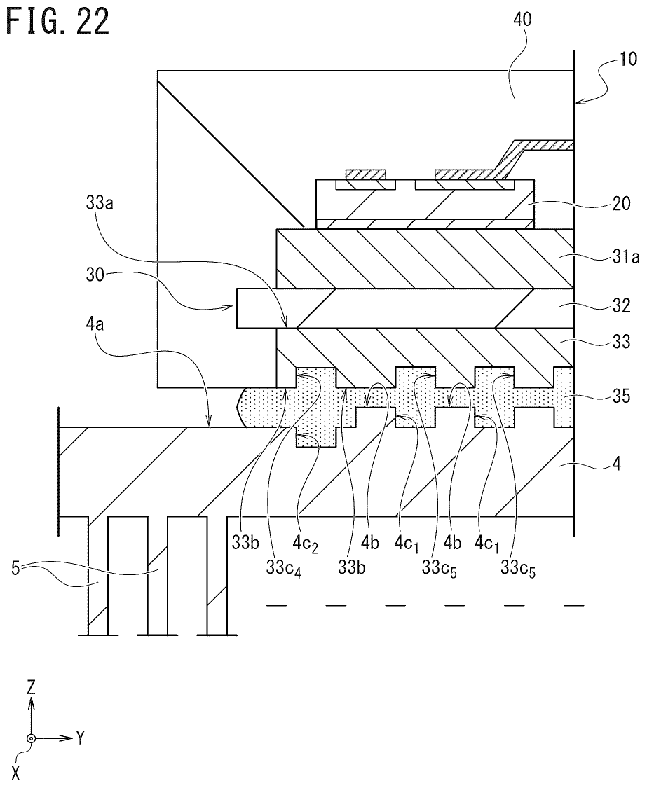

FIG. 22 is a view illustrating Modified Example 1-6 according to the first embodiment of the technology of this disclosure and is a plan view schematically illustrating a longitudinal sectional structure.

As illustrated in FIG. 22, Modified Example 1-6 is achieved in combination of Modified Example 1-4 and Modified Example 1-5.

That is, as illustrated in FIG. 22, the second joined surface portion 33b of the heat dissipation plate 33 according to Modified Example 1-6 includes the fourth recess 33c₄ and the fifth recesses 33c₅ recessed in a direction away from the first joined surface portion 3a side of the heat sink 3. Similarly to Modified Example 1-4, the fourth recess 33c₄ is placed at a position overlapping with the second recess 4c₂ in a plan view and extends along the X-direction similarly to the second recess 4c₂. Similarly to Modified Example 1-5, the fifth recesses 33c₅ are placed at positions overlapping with the first recesses 4c₁ in a plan view and extends along the X-direction similarly to the first recesses 4c₁.

Modified Example 1-6 can also yield effects similar to those of the first embodiment and can enhance the joining function of the thermally-conductive bonding material 35 in the peripheral portion and the central portion of the heat dissipation plate 33 more than the first embodiment.

### Second Embodiment

The second embodiment deals with a case where “the protrusions, the first recess, and the second recess” in the technology of this disclosure are provided for a heat dissipation plate side.

In the second embodiment, reference signs are changed so as to correspond to the reference sign of the heat dissipation plate 33 such that “the protrusion 4b, the first recess 4c₁, and the second recess 4c₂” in the first embodiment are replaced with “a protrusion 33b, a first recess 33c₁, and a second recess 33c₂.”

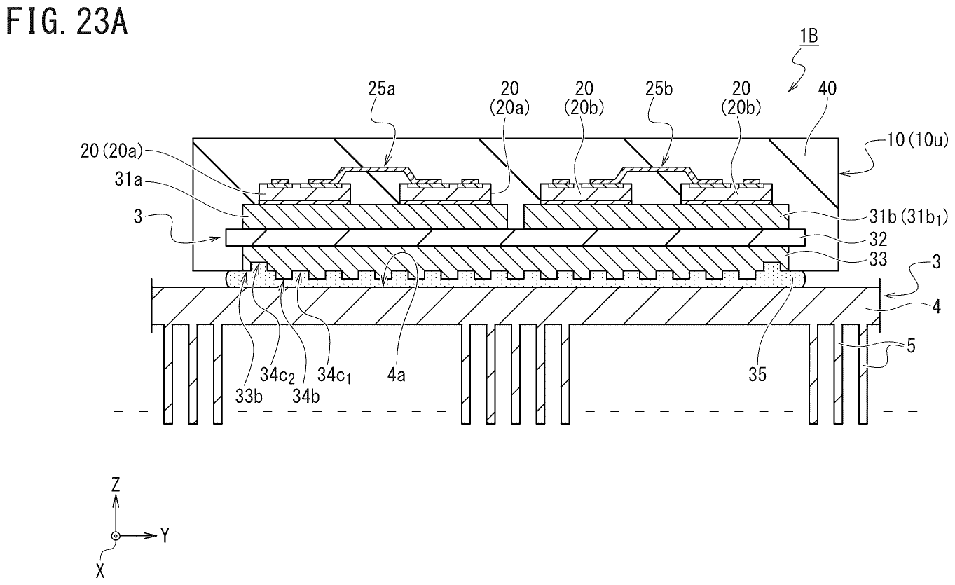

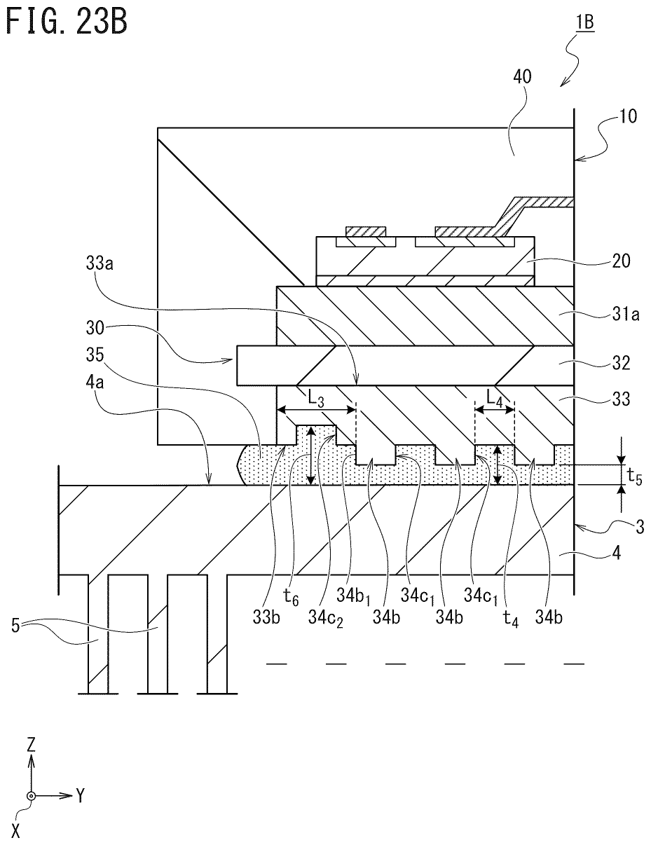

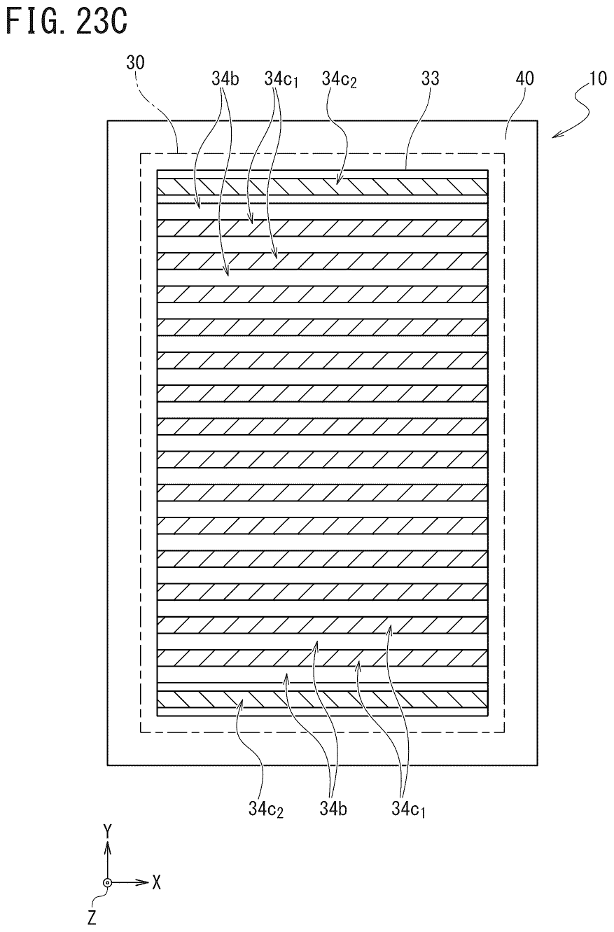

FIG. 23A is a longitudinal sectional view schematically illustrating a longitudinal sectional structure of a power conversion device according to the second embodiment of the technology of this disclosure.

FIG. 23B is a main longitudinal sectional view illustrating part of FIG. 23A in an enlarged manner.

FIG. 23C is a bottom plan view of a semiconductor module illustrated in FIG. 23A.

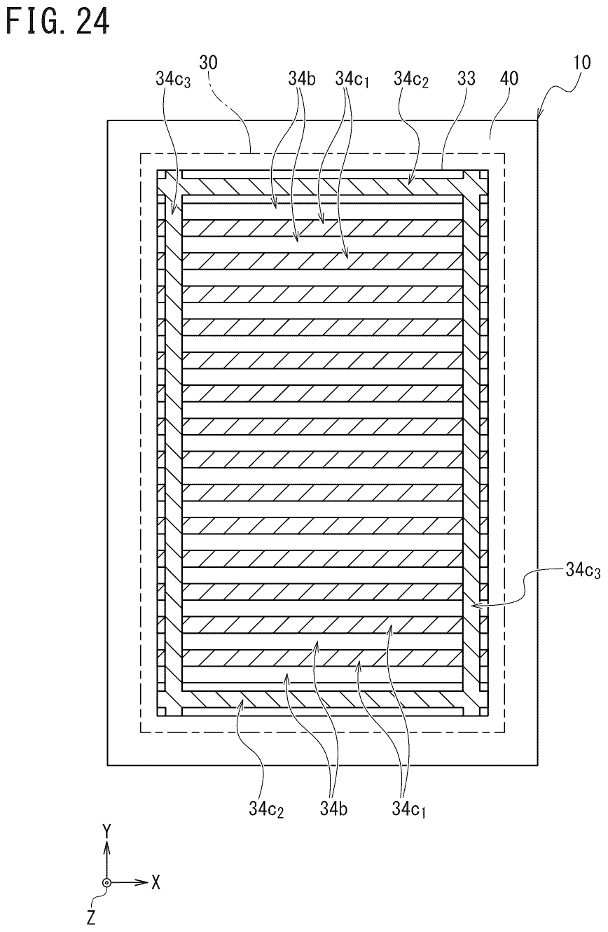

FIG. 24 is a bottom plan view of the semiconductor module provided on a heat sink.

As illustrated in FIG. 23A, a power conversion device 1B according to the second embodiment of the technology of this disclosure basically has a configuration similar to that of the power conversion device 1A according to the first embodiment but is different from the power conversion device 1B in the following configuration.

That is, as illustrated in FIG. 23A and FIG. 23B, in the power conversion device 1B according to the second embodiment, the second joined surface portion 33b of the heat dissipation plate 33 provided for the semiconductor module 10 includes the protrusions 34b, the first recesses 34c₁, and the second recesses 34c₂. In an overlapping region where the heat dissipation plate 33 of the semiconductor module 10 overlaps with the first joined surface portion 4a of the heat sink 3, the first joined surface portion 4a of the heat sink 3 is uniformly flat.

More specifically, as illustrated in FIG. 23B, the second joined surface portion 33b of the heat dissipation plate 33 includes a plurality of protrusions 34b protruding toward the first joined surface portion 4a side of the heat sink 3, the first recesses 34c₁ each placed between two adjacent protrusions 34b and recessed in a direction away from the first joined surface portion 4a side of the heat sink 3, and the second recesses 34c₂ placed outward of the plurality of protrusions 34b and recessed in a direction away from the first joined surface portion 4a side of the heat sink 3. That is, in an overlapping region where the first joined surface portion 4a of the heat sink 3 overlaps with the second joined surface portion 33b of the heat dissipation plate 33 in a plan view, the second joined surface portion 33b of the heat dissipation plate 33 has a recessed-protruding shape (rough shape) including the protrusions 34b, the first recesses 34c₁, and the second recesses 34c₂.

As illustrated in FIG. 23B, a thickness (film thickness) t₄ at the first recess 34c₁ of the thermally-conductive bonding material 35 is greater than a thickness (film thickness) t₅ at the protrusion 34b, and also a thickness (film thickness) to at the second recess 34c₂ of the thermally-conductive bonding material 35 is greater than the thickness (film thickness) t₄ at the first recess 34c₁. That is, the thermally-conductive bonding material 35 has the thicknesses t₄, t₅, to t₆ satisfy “t₆>t₄>t₅” between the first joined surface portion 4a of the heat sink 3 and the second joined surface portion 33b of the heat dissipation plate 33.

As illustrated in FIG. 23B, a distance L₃ from an outer side wall 34b₁ of an outermost protrusion 34b among the plurality of protrusions 34b to an outer edge of the heat dissipation plate 33 is longer than a distance La (the width of the first recess 34c₁) between two adjacent protrusions 34b.

Here, the thickness t₄ of the thermally-conductive bonding material 35 at the first recess 34c₁ is a thickness (a film thickness) between the first joined surface portion 4a of the heat sink 3 and a bottom surface portion of the first recess 34c₁. The thickness t₅ of the thermally-conductive bonding material 35 at the protrusion 34b is a thickness (a film thickness) between the first joined surface portion 4a of the heat sink 3 and an upper surface portion of the protrusion 34b. The thickness to of the thermally-conductive bonding material 35 at the second recess 34c₂ is a thickness (a film thickness) between the first joined surface portion 4a of the heat sink 3 and a bottom surface portion of the second recess 34c₂. Accordingly, in other words, in the thermally-conductive bonding material 35, the thickness (the film thickness) t₆ between the first joined surface portion 4a and the bottom surface portion of the second recess 34c₂ is thicker than the thickness (the film thickness) t₄ between the first joined surface portion 4a and the bottom surface portion of the first recess 34c₁, and the thickness (the film thickness) t₄ between the first joined surface portion 4a and the bottom surface portion of the first recess 34c₁ is thicker than the thickness (the film thickness) t₅ between the first joined surface portion 4a and the upper surface portion of the protrusion 34b (t₆>t₄>t₅).

As illustrated in FIG. 23C, the protrusions 34b, the first recesses 34c₁, and the second recesses 34c₂ are aligned in the Y-direction and extend linearly in the X-direction. The protrusions 4b, the first recesses 4c₁, and the second recesses 4c₂ reach a side surface portion (an outer peripheral edge) of the heat dissipation plate 33 in a plan view and are terminated at this side surface portion.

In the second embodiment, the thermally-conductive bonding material 35 is also provided over the heat dissipation plate 33 and the resin sealing body 40 in a plan view.

In the second embodiment, in the thermally-conductive bonding material 35, it is preferable that the thickness t₆ at the second recess 34c₂ be equal to or more than 150 μm and the thickness t₅ at the protrusion 34b be equal to or less than 50 μm, for example.

With reference to FIG. 23B, in the second embodiment, the protrusion 34b can be also expressed in other words as a “protrusion 34b protruding from the second joined surface portion 33b toward the first joined surface portion 4a side.”

In addition, the first recess 34c₁ can be also expressed in other words as a “first recess 34c₁ extending from the upper surface of the protrusion 34b toward a side opposite to the first joined surface portion 4a side.”

The second recess 34c₂ can be also expressed in other words as a “second recess 34c₂ extending from the second joined surface portion 33b toward a side opposite to the first joined surface portion 4a side.”

In the second embodiment, the first recess 34c₁ and the second recess 34c₂ can be also expressed in other words as a first groove 34c₁ and a second groove 34c₂.

The power conversion device 1B according to the second embodiment can also yield effects similar to those of the power conversion device 1A according to the first embodiment.

### Modified Examples of Second Embodiment

The following describes modified examples of the second embodiment.

### Modified Example 2-1

FIG. 24 is a view illustrating Modified Example 2-1 according to the second embodiment of the technology of this disclosure and is a bottom plan view of a semiconductor module.

Modified Example 2-1 is achieved by providing the third recess 4c₃ in Modified Example 1-1 on the heat dissipation plate 33 side in the second embodiment. In Modified Example 2-1, the “third recess 4c₃” in Modified Example 1-1 is replaced with a “third recess 34c₃” so that reference signs correspond to the reference sign of the heat dissipation plate 33.

As illustrated in FIG. 24, the second joined surface portion 33b of the heat dissipation plate 33 according to Modified Example 1-2 further includes third recesses 34c₃ extending in the Y-direction. Although not illustrated here in detail, the third recess 34c₃ is recessed to a side opposite to the first joined surface portion 4a side of the heat sink 3, similarly to the second recess 34c₂ illustrated in FIG. 23B, for example. The third recess 34c₃ has a depth similar to that of the second recess 34c₂, for example. A thickness at the third recess 34c₃ of the thermally-conductive bonding material 35 is greater than the thickness (film thickness) t₄ at the first recess 34c₁, similarly to the thickness to at the second recess 34c₂.

As illustrated in FIG. 24, the third recesses 34c₃ are provided on two long-side portion sides of the heat dissipation plate 33 to be arranged along the two long-side portions. The third recesses 34c₃ are provided across the protrusions 34b and the first recesses 34c₁ repeatedly provided in the Y-direction to intersect with the protrusions 34b and the first recesses 34c₁. Similarly to Modified Example 1-2, in Modified Example 2-1, the third recesses 34c₃ intersect with the second protrusions 34c₂ placed outward of the plurality of protrusions 34b.

Modified Example 2-1 can also yield effects similar to those of the first embodiment.

Further, in Modified Example 2-1, the second joined surface portion 33b of the heat dissipation plate 33 further includes the third recesses 34c₃, so that Modified Example 2-1 can also enhance the joining function of the thermally-conductive bonding material 35 in the peripheral portion of the heat dissipation plate 33 more than the first embodiment, similarly to Modified Examples 1-1 and 1-2.

It is noted that the depth of the third recess 34c₃ may be shallower than the second recess 34c₂ or may be deeper than the second recess 34c₂.

### Other Modified Examples

In the power conversion device 1B according to the second embodiment, Modified Examples 1-3 to 1-6 can be also combined with each other.

### Third Embodiment

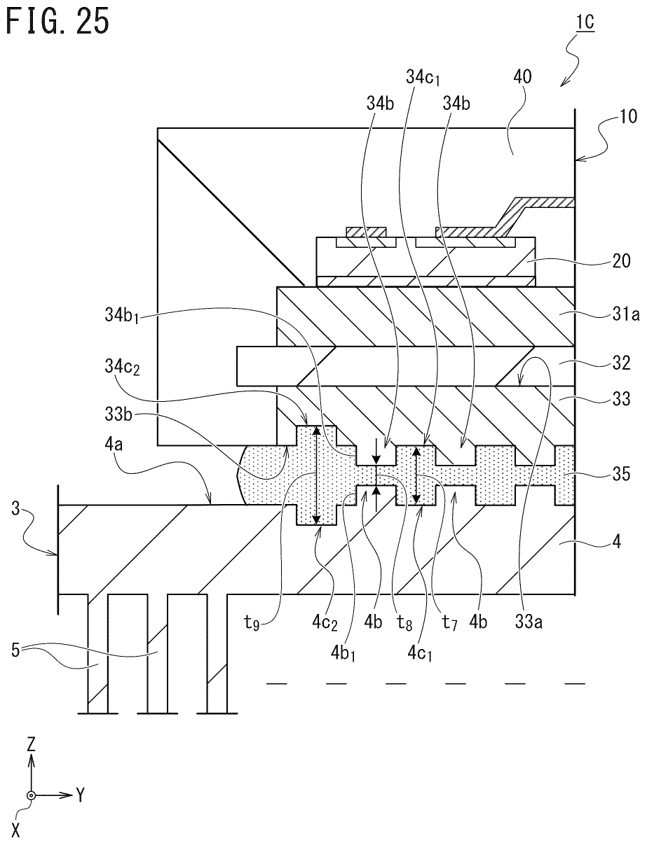

FIG. 25 is a longitudinal sectional view schematically illustrating part of a longitudinal sectional structure of a power conversion device according to the third embodiment of the technology of this disclosure.

The third embodiment is achieved by combining the first embodiment with the second embodiment.

That is, as illustrated in FIG. 25, in a power conversion device 1C according to the third embodiment of the technology of this disclosure, the first joined surface portion 4a of the heat sink 3 includes the protrusions 4b, the first recesses 4c₁, and the second recesses 4c₂, and the second joined surface portion 33b of the heat dissipation plate 33 of the semiconductor module 10 includes the protrusions 34b, the first recesses 34c₁, and the second recesses 34c₂. The protrusions 4b, the first recesses 4c₁, and the second recesses 4c₂ on the heat sink 3 side overlap with the protrusions 34b, the first recesses 34c₁, and the second recesses 34c₂ on the heat dissipation plate 33 side, respectively, in a plan view. In an overlapping region where the first joined surface portion 4a of the heat sink 3 overlaps with the second joined surface portion 33b of the heat dissipation plate 33 in a plan view, the first joined surface portion 4a of the heat sink 3 has a recessed-protruding shape (rough shape) including the protrusions 4b, the first recesses 4c₁, and the second recesses 4c₂. The second joined surface portion 33b of the heat dissipation plate 33 has a recessed-protruding shape (rough shape) including the protrusions 34b, the first recesses 34c₁, and the second recesses 34c₂.

As illustrated in FIG. 25, a thickness (film thickness) t₇ at the first recess 4c₁ and the first recess 34c₁ of the thermally-conductive bonding material 35 is greater than a thickness (film thickness) t₈ at the protrusion 4b and the protrusion 34b. A thickness (film thickness) t₉ at the second recess 4c₂ and the second recess 34c₂ of the thermally-conductive bonding material 35 is greater than a thickness (film thickness) t₇ at the first recess 4c₁ and the first recess 34c₁. That is, the thermally-conductive bonding material 35 in the third embodiment has the thicknesses t₇, t₈, t₉ to satisfy “t₉>t₇>t₈” between the first joined surface portion 4a of the heat sink 3 and the second joined surface portion 33b of the heat dissipation plate 33.

In the thermally-conductive bonding material 35 in the third embodiment, the thickness t₇ at the first recess 4c₁ and the first recess 34c₁ is greater than the thickness t₁ at the first recess 4c₁ in the first embodiment and the thickness t₄ at the first recess 34c₁ in the second embodiment (t₇>t₁, t₄). In the thermally-conductive bonding material 35 in the third embodiment, the thickness ty at the second recess 4c₂ and the second recess 34c₂ is greater than the thickness t₃ at the second recess 4c₂ in the first embodiment and the thickness to at the second recess 34c₂ in the second embodiment (t₉>t₃, t₆).

Here, the thickness t₇ of the thermally-conductive bonding material 35 at the first recess 4c₁ and the first recess 34c₁ is a thickness (a film thickness) between the bottom surface portion of the first recess 4c₁ and the bottom surface portion of the first recess 34c₁. The thickness t₈ of the thermally-conductive bonding material 35 at the protrusion 4b and the protrusion 34b is a thickness (a film thickness) between the upper surface portion of the protrusion 4b and the upper surface portion of the protrusion 34b. The thickness t₉ of the thermally-conductive bonding material 35 at the second recess 4c₂ and the second recess 34c₂ is a thickness (a film thickness) between the bottom surface portion of the second recess 4c₂ and the bottom surface portion of the second recess 34c₂. Accordingly, in other words, in the thermally-conductive bonding material 35 in the third embodiment, the thickness (the film thickness) t₉ between the bottom surface of the second recess 4c₂ and the bottom surface of the second recess 34c₂ is greater than the thickness (the film thickness) t₇ between the bottom surface of the first recess 4c₁ and the bottom surface of the first recess 34c₁, and the thickness (the film thickness) t₇ between the bottom surface of the first recess 4c₁ and the bottom surface of the first recess 34c₁ is greater than the thickness (the film thickness) t₈ between the protrusion 4b and the protrusion 34b (t₉>t₇>t₈).

The power conversion device 1C according to the third embodiment can also yield effects similar to those of the power conversion device 1A according to the first embodiment.

In the power conversion device 1C according to the third embodiment, since the thickness of the thermally-conductive bonding material 35 satisfies “t₉>t₃, t₆,” it is possible to secure a heat dissipation function equivalent to the heat dissipation function in the first embodiment and the second embodiment and to enhance the joining function of the thermally-conductive bonding material 35 in the central portion and the peripheral portion of the heat dissipation plate more than in the first embodiment and the second embodiment.

### Other Embodiments

The above embodiments deal with an example in which the technology of this disclosure is applied to a power conversion device including the two-element packaged type (2-in-1 type) semiconductor module 10 provided on the heat sink 3. However, the technology of this disclosure is not limited to the power conversion device including the two-element packaged type (2-in-1 type) semiconductor module 10, and the technology of this disclosure is also applicable to a power conversion device in which a one-element packaged type (1-in-1 type) semiconductor module or a multiple-element packaged type semiconductor module is provided on a heat sink.

The above embodiments deal with the heat sink 3 including the base member 4 and the heat dissipation fins 5, but the technology of this disclosure is also applicable to a case where a heat sink including only the base member 4, that is, a heat sink called a heat spreader is used.

The technology of this disclosure has been described in detail based on the embodiments and the modified examples thereof, but the technology of this disclosure is not limited to the above embodiments and the modified examples and is naturally modifiable within a range that does not deviate from the gist of the technology of this disclosure.

### REFERENCE SIGNS LIST

1A, 1B, 1C: power conversion device (electronic device)
2: power unit
3: heat sink
4: base member
4a: first joined surface portion
4b: protrusion
4c₁: first recess
4c₂: second recess
5: heat dissipation fin
8P: positive power line
8N: negative power line
9: three-phase induction motor
10, 10u, 10v, 10w: semiconductor module (power semiconductor module)
11a: upper arm
11b: lower arm
12: resin sealing body
13: positive external terminal
14: negative external terminal
16: output external terminal
17a: first control external terminal
17b: second control external terminal
20: transistor chip
21a: first main electrode
21b: second main electrode
21c: control electrode
22: second joined surface portion
22b: protrusion
22c₁: first recess
22c₂: second recess
23: positive lead
24: negative leads
25a: first relay lead
25b: second relay lead
26: output lead
27a: first control lead
27b: second control lead
30: supporting substrate
31a: first electrically-conductive plate
31b: second electrically-conductive plate
31c: third electrically-conductive plate
32: insulating plate
33: heat dissipation plate (metal plate)
34b: protrusion
34c₁: first recess
34c₂: second recess
34c₃: third recess
34c₄: fourth recess
34c₅: fifth recess
35: thermally-conductive bonding material
L₁: distance
L₂: distance
h₁₀: height
p₁₀: arrangement pitch
t₁, t₂, t₃, t₄, t₅, t₆, t₇, t₈, t₉, t₁₀: thickness

1. An electronic device comprising:
a heat sink; and
a semiconductor module provided on the heat sink,
wherein the heat sink includes a first joined surface portion,
wherein the semiconductor module includes
a heat dissipation plate including a second joined surface portion joined to the first joined surface portion via a thermally-conductive bonding material, and
a transistor chip placed on a side of the heat dissipation plate which is opposite to the second joined surface portion,
wherein at least one joined surface portion out of the first joined surface portion and the second joined surface portion includes
a plurality of protrusions protruding toward the other joined surface portion out of the first joined surface portion and the second joined surface portion,
a first recess placed between the plurality of protrusions and recessed in a direction away from the other joined surface portion, and
a second recess placed outward of the plurality of protrusions and recessed in the direction away from the other joined surface portion, and
wherein a thickness at the first recess of the thermally-conductive bonding material is greater than a thickness of the thermally-conductive bonding material at the protrusions, and
a thickness at the second recess of the thermally-conductive bonding material is greater than the thickness at the first recess.

2. The electronic device according to claim 1,
wherein the thickness of the thermally-conductive bonding material at the first recess is a thickness between the other joined surface portion and a bottom surface of the first recess,
wherein the thickness of the thermally-conductive bonding material at the protrusions is a thickness between the other joined surface portion and the protrusions, and
wherein the thickness of the thermally-conductive bonding material at the second recess is a thickness between the other joined surface portion and a bottom surface of the second recess.

3. The electronic device according to claim 1, wherein a distance from an outer side wall of an outermost protrusion among the plurality of protrusions to an outer edge of the heat dissipation plate is longer than a distance between two adjacent protrusions among the plurality of protrusions.

4. The electronic device according to claim 1, wherein the protrusions, the first recess, and the second recess are aligned to extend linearly.

5. The electronic device according to claim 4, wherein the protrusions, the first recess, and the second recess are provided across the semiconductor module in a plan view.

6. The electronic device according to claim 1,
wherein the semiconductor module further includes a sealing body covering an outer periphery of the heat dissipation plate and the transistor chip, and
wherein the thermally-conductive bonding material is provided over the heat dissipation plate and the sealing body in a plan view.

7. The electronic device according to claim 1,
wherein the thickness of the thermally-conductive bonding material at the second recess is equal to or more than 150 μm, and
wherein the thickness of the thermally-conductive bonding material at the protrusions is equal to or less than 50 μm.

8. The electronic device according to claim 1,
wherein the transistor chip includes a plurality of transistor chips each including a first main electrode, a second main electrode, and a control electrode,
wherein the first main electrodes of the plurality of transistor chips is electrically connected to each other,
wherein the second main electrodes of the plurality of transistor chips are electrically connected to each other, and
wherein the control electrodes of the plurality of transistor chips are electrically connected to each other.

9. The electronic device according to claim 8, further comprising a supporting substrate which includes an insulating plate including a main surface portion and a back surface portion opposite to each other, a first electrically-conductive plate and a second electrically-conductive plate placed on the main surface portion side of the insulating plate, and the heat dissipation plate placed on the back surface portion side of the insulating plate,
wherein the plurality of transistor chips includes a first transistor chip including a second main electrode joined to the first electrically-conductive plate, and a second transistor chip including a second main electrode joined to the second electrically-conductive plate.
